(19) United States
(12) Patent Application Publication
(10) Pub. No.: US 2014/0022377 A1
(43) Pub. Date: Jan. 23, 2014

(54) MARK DETECTION METHOD, EXPOSURE METHOD AND EXPOSURE APPARATUS, AND DEVICE MANUFACTURING METHOD

(71) Applicant: Yuho Kanaya, Kumagaya-shi (JP)

(72) Inventor: Yuho Kanaya, Kumagaya-shi (JP)

(73) Assignee: NIKON CORPORATION, Tokyo (JP)

(21) Appl. No.: 13/885,519

(22) PCT Filed: Nov. 29, 2011
(86) PCT No.: PCT/JP2011/006646

§ 371 Date: Sep. 19, 2013

(30) Foreign Application Priority Data
Nov. 29, 2010 (JP) 2010-264935

(51) Int. Cl. G03F 9/00

(52) U.S. Cl. CPC G03F 9/7088
USPC 348/95

(57) ABSTRACT

An alignment mark provided on a wafer is imaged using an alignment system, while driving a wafer stage based on measurement results of a position measurement system, and a position of the alignment mark is obtained from an imaging position of the alignment mark obtained from the imaging results and a position of the wafer stage at the time of imaging obtained from the measurement results of the position measurement system. During the imaging of the alignment mark, the wafer stage is uniformly driven by a moving distance which is an integral multiple of the measurement period of the position measurement system, and a position of the wafer stage at the time of imaging is obtained from an average of the measurement results of the position measurement system. This allows alignment measurement to be performed with good precision, without being affected by periodic errors of the position measurement system.

### TECHNICAL FIELD

The present invention relates to mark detection methods, exposure methods and exposure apparatuses, and device manufacturing methods, and more particularly to a mark detection method to detect a mark formed on an object, an exposure method using the detection method and an exposure apparatus that executes the exposure method, and a device manufacturing method using the exposure method.

### BACKGROUND ART

In a lithography process to manufacture electronic devices (microdevices) such as semiconductor devices (integrated circuits and the like), liquid crystal display devices and the like, for example, a projection exposure apparatus of a step-and-repeat method (a so-called stepper), or a projection exposure apparatus of a step-and-scan method (a so-called scanner) and the like are mainly used that transfer a pattern of a photomask or a reticle (hereinafter collectively referred to as a “reticle”) onto an object subject to exposure such as a wafer, a glass plate and the like on which a photosensitive agent such as a photoresist and the like is coated (hereinafter collectively referred to as a “wafer”), via a projection optical system.

Semiconductor devices and the like are formed by overlaying ten or more layers of device patterns, therefore, in the projection exposure apparatus, it is required to accurately align a pattern formed on a reticle on a pattern which is already formed on a wafer. Therefore, in recent years, the Enhanced Global Alignment (EGA) method is widely employed when aligning a wafer (wafer alignment) in which alignment marks arranged in a part of a plurality of shot areas are detected, and by performing statistical processing on the detection results, arrays of all shot areas, and furthermore, distortion of a pattern within a shot area (in-shot error), are obtained with high precision (for example, refer to Patent Literature (PTL) 1, PTL 2 and the like).

In the detection of alignment marks described above, a position of a wafer stage holding a wafer is measured by a measuring instrument such as an encoder (or an interferometer) and the like, and a wafer stage is driven based on the measurement results so that alignment marks subject to detection are positioned and detected within a detection field of an alignment system. Here, along with finer device rules, it has become obvious that measurement errors of measuring instruments, especially periodical measurement errors (periodic errors) become an error factor of an extent that cannot be ignored with respect to detection accuracy of alignment marks, or in turn, with respect to alignment accuracy of a wafer. Furthermore, while alignment marks are designed to be formed at the same position in every wafer, because the mounted state on the wafer stage changes each time a wafer is mounted, the position of alignment marks on a position measurement coordinate system of the wafer stage may differ each time detection is performed. Therefore, due to periodic errors of measuring instruments, detection reproducibility of alignment marks also worsens.

### CITATION LIST

### Patent Literature

[PTL 1] U.S. Pat. No. 4,780,617
[PTL 2] U.S. Pat. No. 6,876,946

### SUMMARY OF INVENTION

### Means for Solving the Problems

According to a first aspect of the present invention, there is provided a mark detection method to detect a mark present on a movable body, the method comprising: imaging the mark with a mark detection system provided externally to the movable body when the movable body is driven in a predetermined direction while measuring position information of the movable body with a position measurement system that has a measurement period in principle, during the drive of the movable body; and obtaining a position of the mark, using an imaging position obtained from imaging results of the mark and a position of the movable body at the time of imaging of the mark obtained from measurement results of the position measurement system.

According to this method, it becomes possible to reduce periodic measurement errors (periodic errors) of the position measurement system and to perform mark detection with good accuracy.

According to a second aspect of the present invention, there is provided an exposure method to form a pattern on an object by irradiating an energy beam, the method comprising: detecting at least one of a mark on the movable body holding the object and a mark on the object by the mark detection method of the first aspect; and forming the pattern on the object by driving the movable body holding the object based on detection results of the mark and alignment of the object, and irradiating the energy beam on the object.

According to this method, because mark detection with high precision can be performed by the mark detection method described above, by driving the movable body holding the object and positioning the object based on results of this mark detection, exposure with high precision becomes possible.

According to a third aspect of the present invention, there is provided a device manufacturing method, comprising: exposing an object by the exposure method according to the second aspect; and developing the object which has been exposed.

According to a fourth aspect of the present invention, there is provided an exposure apparatus which forms a pattern on an object by irradiating an energy beam, the apparatus comprising: a movable body which moves holding the object; a position measurement system having a measurement period in principle that measures position information of the movable body; a mark detection system provided externally to the movable body that images a mark on the object; and a controller which obtains a position of a mark by driving the movable body in a predetermined direction while measuring position information of the movable body with the position measurement system and imaging the mark on the object held on the movable body using the mark detection system during the driving of the movable body, using an imaging position of the mark obtained from imaging results of the mark and a position of the movable body at the time of imaging of the mark which is obtained from measurement results of the position measurement system.

According to this apparatus, by reducing periodic measurement errors (periodic errors) of the position measurement system, mark detection can be performed with good accuracy. Further, by driving the movable body holding the object and aligning the object based on results of this mark detection, exposure with high precision is becomes possible.

### BRIEF DESCRIPTION OF DRAWINGS

FIG. 1 is a view schematically showing a structure of an exposure apparatus related to an embodiment.

FIG. 2 is a planar view of a wafer stage.

FIG. 3 is a planar view showing a placement of a stage device and an interferometer equipped in the exposure apparatus of FIG. 1.

FIG. 4 is a planar view showing measurement devices other than an interferometer system equipped in the exposure apparatus of FIG. 1, along with the wafer stage.

FIG. 5 is a planar view showing a placement of encoder heads (X head, Y head) and alignment systems.

FIG. 6 is a block diagram showing an input/output relation of a main controller which mainly structures a control system of the exposure apparatus related to the embodiment.

FIG. 7 is a view showing a state where the first half processing of Pri-BCHK is performed.

FIG. 8 is a view showing a state where alignment marks arranged in three first alignment shot areas are simultaneously detected, using alignment systems AL1, AL2₂, and AL2₃.

FIG. 9 is a view showing a state where alignment marks arranged in five second alignment shot areas are simultaneously detected, using alignment systems AL1, and AL2₁ to AL2₄.

FIG. 10 is a view showing a state where the second half processing of Pri-BCHK is performed.

FIG. 11 is a view showing an example of a structure of an encoder.

FIGS. 12A and 12B are views used to explain a method of analysis of measurement results of the encoder.

FIGS. 13A and 13B are views used to explain a mark detection method for detecting an alignment mark using the alignment system, and FIG. 13C is a view showing a driving velocity of the wafer stage at the time of mark detection and a generation timing of a measurement clock.

FIG. 14 is a view (No. 1) used to explain a detection method of an alignment mark by an alternate scanning method.

FIG. 15 is a view (No. 2) used to explain a detection method of an alignment mark by an alternate scanning method.

### BEST MODE FOR CARRYING OUT THE INVENTION

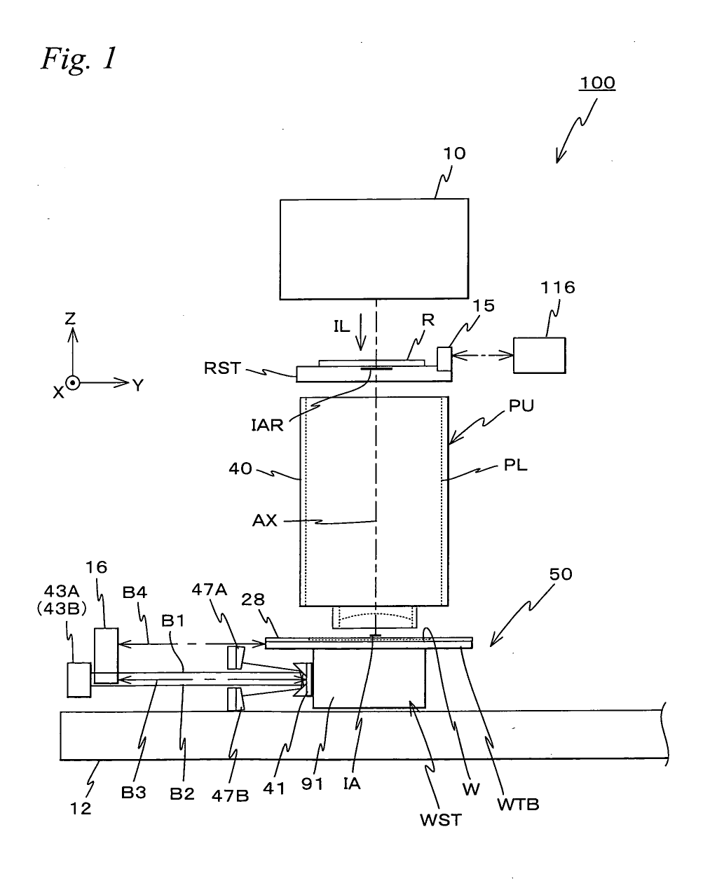

Hereinafter, an embodiment will be described, based on FIGS. 1 to 15.

FIG. 1 schematically shows a structure of an exposure apparatus 100 of an embodiment. Exposure apparatus 100 is a projection exposure apparatus of a step-and-scan method, or a so-called scanner. As it will be described later on, a projection optical system PL is provided in the present embodiment. Hereinafter, the description will be made with a direction parallel to an optical axis AX of projection optical system PL serving as a Z-axis direction, a scanning direction in which a reticle R and a wafer W are relatively scanned within a plane orthogonal to the Z-axis direction serving as a Y-axis direction, a direction orthogonal to the Z-axis and the Y-axis serving as an X-axis direction, and rotation (tilt) directions around the X-axis, the Y-axis, and the Z-axis serving as a θx direction, a θy direction, and a θz direction, respectively.

Exposure apparatus 100 is equipped with an illumination system 10, a reticle stage RST, a projection unit PU, a stage device 50 having a wafer stage WST, and a control system and the like for these parts. In FIG. 1, wafer W is mounted on wafer stage WST.

Illumination system 10 illuminates a slit shaped illumination area IAR on reticle R set (restricted) by a reticle blind (also called a masking system) with an illumination light (exposure light) IL, at an almost uniform illuminance. The structure of illumination system 10 is disclosed, for example, in U.S. Patent Application Publication No. 2003/0025890 and the like. Here, as illumination light IL, as an example, an ArF excimer laser beam (wavelength 193 nm) is used.

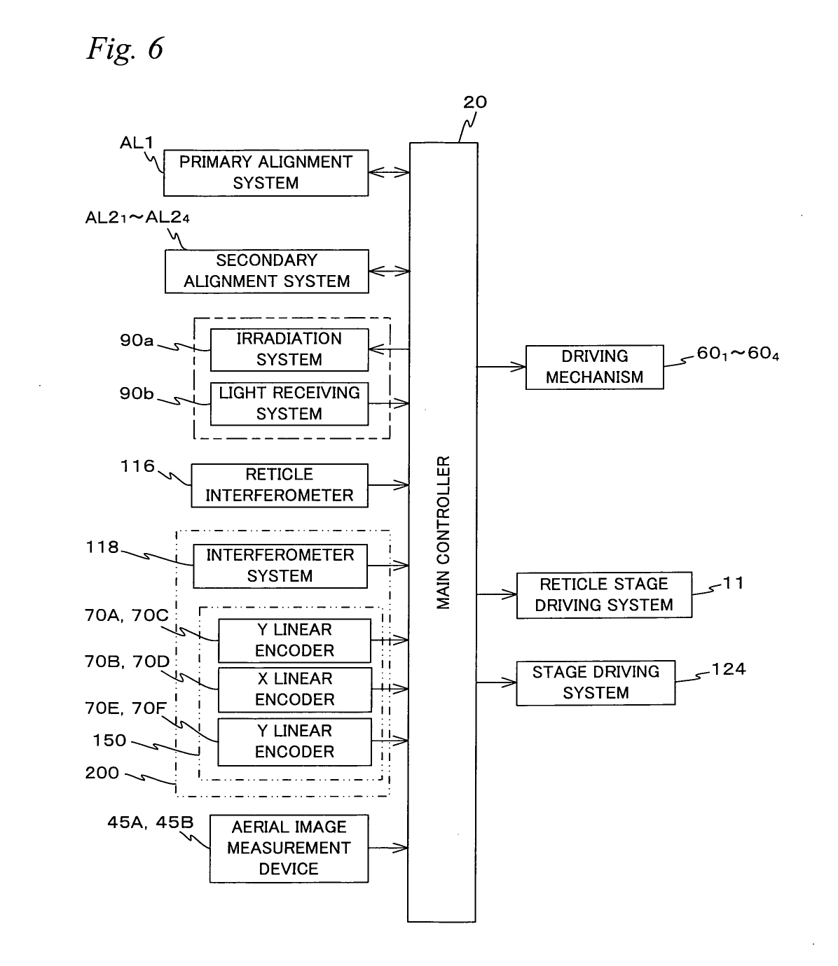

On reticle stage RST, reticle R on which a circuit pattern and the like is formed on its pattern surface (the lower surface in FIG. 1) is fixed, for example, by vacuum chucking. Reticle stage RST, for example, can be finely driven within an XY plane by a reticle stage driving system 11 (not shown in FIG. 1, refer to FIG. 6) including a linear motor and the like, and can also be driven at a predetermined scanning velocity in the scanning direction (the Y-axis direction which is the horizontal direction of the page surface of FIG. 1).

Position information of reticle stage RST within the XY plane (including rotation information in the θz direction) is constantly detected by a reticle laser interferometer (hereinafter, referred to as a “reticle interferometer”) 116, via a movable mirror 15 (or a reflection surface formed on an edge surface of reticle stage RST), at a resolution of, for example, around 0.25 nm. Measurement values of reticle interferometer 116 are sent to a main controller 20 (not shown in FIG. 1, refer to FIG. 6).

Projection unit PU is placed below reticle stage RST in FIG. 1. Projection unit PU includes a barrel 40, and projection optical system PL held within barrel 40. As projection optical system PL, for example, a dioptric system is used consisting of a plurality of optical elements (lens elements) arranged along optical axis AX parallel to the Z-axis direction. Projection optical system PL, for example, is double telecentric, and has a predetermined projection magnification (for example, ¼ times, ⅕ times or ⅛ times and the like). Therefore, when illumination system 10 illuminates illumination area IAR on reticle R, by illumination light IL having passed through reticle R placed so that a first plane (object plane) of projection optical system PL and the pattern surface are substantially coincident, a reduced image of a circuit pattern (a reduced image of part of a circuit pattern) within illumination area IAR of reticle R is formed via projection optical system PL (projection unit PU), in an area (hereinafter, also referred to as an exposure area) IA, conjugate to illumination area IAR, on wafer W which is placed on a second plane (image plane) side of projection optical system PL and whose surface is coated with a resist (sensitive agent). And, by a synchronous drive of reticle stage RST and wafer stage WST, reticle R is relatively moved in the scanning direction (the Y-axis direction) with respect to illumination area IAR (illumination light IL), while by relatively moving wafer W in the scanning direction (the Y-axis direction) with respect to exposure area IA (illumination light IL), scanning exposure of a shot area (divided area) on wafer W is performed, and a pattern of reticle R is transferred on the shot area. That is, in the present embodiment, a pattern of reticle R is generated on wafer W by illumination system 10 and projection optical system PL, and by illumination light IL exposing a sensitive layer (resist layer) on wafer W, the pattern is formed on wafer W. Although it is not shown, while projection unit PU is mounted on a barrel surface plate supported by three support columns via a vibration-proof mechanism, as disclosed in, for example, PCT International Publication No. 2006/038952, projection unit PU can be supported in a suspended manner, with respect to a main frame member which is not shown placed above projection unit PU or to a base member where reticle stage RST is placed.

Stage device 50, as shown in FIG. 1, is equipped with wafer stage WST placed above base board 12, a measurement system 200 (refer to FIG. 6) which measures position information of wafer stage WST, and a stage driving system 124 (refer to FIG. 6) which drives wafer stage WST and the like. Measurement system 200, as shown in FIG. 6, includes an interferometer system 118, an encoder system 150 and the like.

Wafer stage WST is supported above base board 12 by a non-contact bearing which is not shown, such as for example, an air bearing and the like, via a clearance gap (clearance, gap) of around several μm. Further, wafer stage WST can be driven in predetermined strokes in the X-axis direction and the Y-axis direction by stage driving system 124 (refer to FIG. 6) which includes a linear motor and the like.

Wafer stage WST includes a stage main section 91, and a wafer table WTB mounted on stage main section 91. This wafer table WTB and stage main section 91 are structured drivable in directions of six degrees of freedom (in each of the X-axis, the Y-axis, the Z-axis, the θx, the θy, and the θz directions) with respect to base board 12, by a driving system that includes a linear motor and a Z-leveling mechanism (including a voice coil motor and the like).

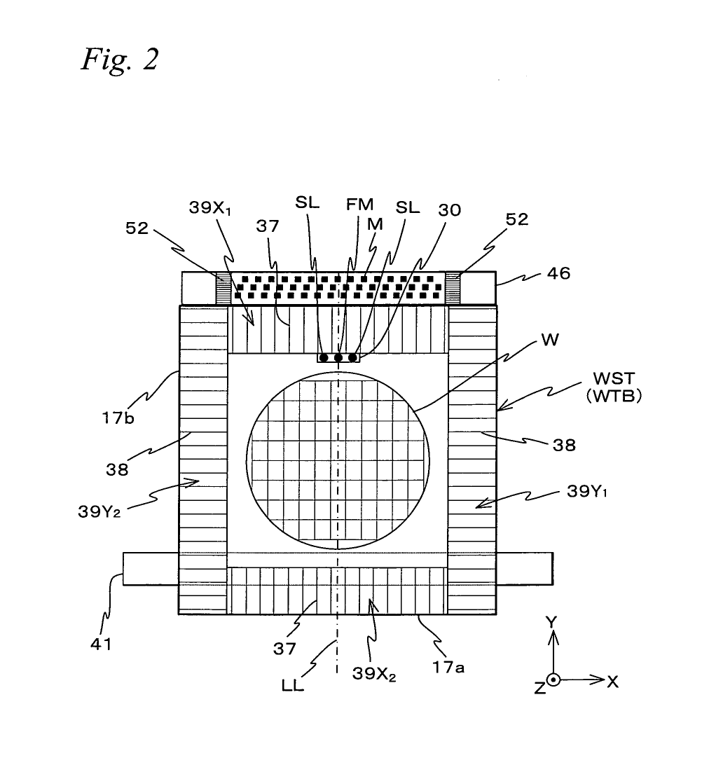

In the center on the upper surface of wafer table WTB, a wafer holder (not shown) is provided that holds wafer W by vacuum chucking and the like. As is shown in FIG. 2, a measurement plate 30 is provided on the +Y side of the wafer holder (wafer W) on the upper surface of wafer table WTB. In this measurement plate 30, a fiducial mark FM is provided in the center, and on both sides of fiducial mark FM in the X-axis direction, a pair of aerial image measurement slit plates SL is provided. In each aerial image measurement slit plate SL, although it is not shown, a line shaped opening pattern (an X slit) of a predetermined width (for example, 0.2 μm) whose longitudinal direction is in the Y-axis direction, and a line shaped opening pattern (a Y slit) of a predetermined width (for example, 0.2 μm) whose longitudinal direction is in the X-axis direction are formed.

And, corresponding to each aerial image measurement slit plate SL, an optical system including a lens and the like and a photodetection element such as a photomultiplier (photomultiplier tube (PMT)) and the like are placed inside wafer table WTB, and a pair of aerial image measurement devices 45A, 45B (refer to FIG. 6) similar to the one disclosed in, U.S. Patent Application Publication No. 2002/0041377 and the like is provided. Measurement results (output signals of the photodetection elements) of aerial image measurement devices 45A, 45B are sent to main controller 20 (refer to FIG. 6), after a predetermined signal processing is applied by a signal processing device (not shown).

Further, on the upper surface of wafer table WTB, a scale used in encoder system 150 is formed. To be more specific, in an area on one side and the other side in the X-axis direction (the lateral direction of the page surface in FIG. 2) on the upper surface of wafer table WTB, Y scales 39Y₁, 39Y₂ are formed, respectively. Y scales 39Y₁, 39Y₂ are structured, for example, by a reflection type grating (for example, a diffraction grating) whose period direction is in the Y-axis direction, having grid lines 38 whose longitudinal direction is in the X-axis direction arranged at a predetermined pitch in the Y-axis direction.

Similarly, in an area on one side and the other side in the Y-axis direction (the vertical direction of the page surface in FIG. 2) on the upper surface of wafer table WTB, X scales 39X₁, 39X₂ are formed, respectively, in a state provided between Y scales 39Y₁ and 39Y₂. X scales 39X₁, 39X₂ are structured, for example, by a reflection type grating (for example, a diffraction grating) whose period direction is in the X-axis direction, having grid lines 37 whose longitudinal direction is in the Y-axis direction arranged at a predetermined pitch in the X-axis direction.

Incidentally, the pitch of grid lines 37 and 38 is set, for example, to 1 μm. In FIG. 2 and in other drawings, the pitch of the gratings is illustrated larger than the actual pitch, for the sake of illustration.

Further, to protect the diffraction gratings, it is also effective to cover the diffraction gratings with a glass plate that has a low thermal expansion coefficient. Here, as the glass plate, a plate having the same level of thickness as the wafer such as for example, a thickness of 1 mm, can be used, and the plate is installed on the upper surface of wafer table WTB so that the surface of the glass plate is set to the same height as (flush with) the surface of the wafer.

Further, on a −Y edge surface and a −X edge surface of wafer table WTB, as shown in FIG. 2, a reflection surface 17a and a reflection surface 17b that are used in an interferometer system to be described later on are provided, respectively.

Further, on the +Y side surface of wafer table WTB, as shown in FIG. 2, a fiducial bar (hereinafter, shortly referred to as an FD bar) 46 extending in the X-axis direction that is similar to a CD bar disclosed in, U.S. Patent Application Publication No. 2008/0088843, is attached. Close to the end on one side and the other side in the longitudinal direction of FD bar 46, reference gratings (for example, diffraction gratings) 52 whose period direction is in the Y-axis direction are formed, in an arrangement symmetric to a center line LL. Further, a plurality of fiducial marks M is formed on the upper surface of FD bar 46. As each fiducial mark M, a two-dimensional mark having a dimension that can be detected by an alignment system which is described later on is used.

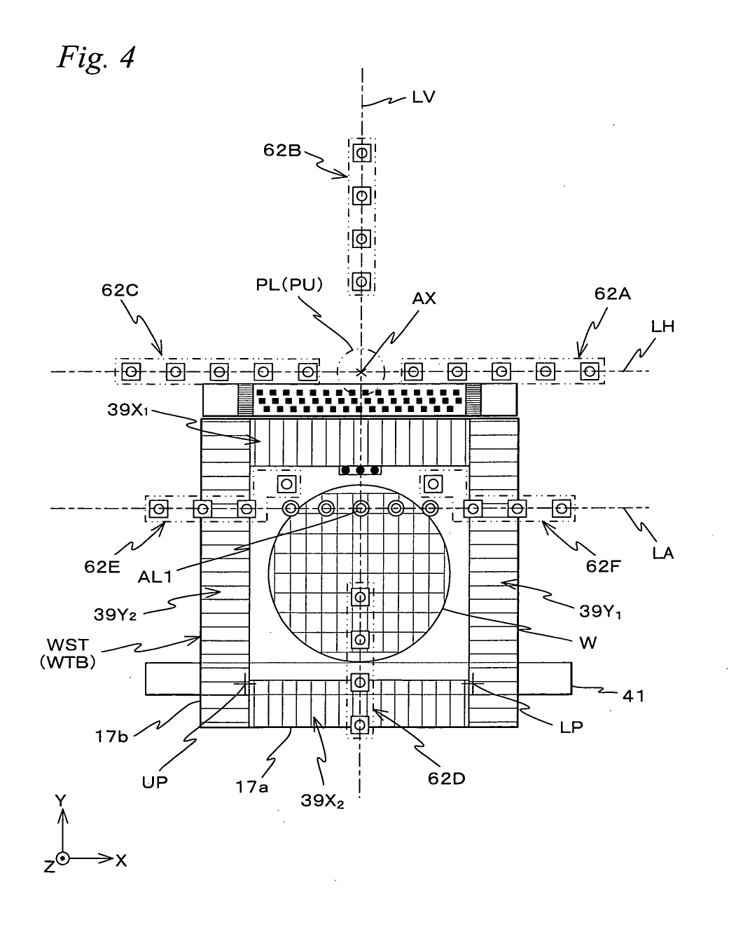

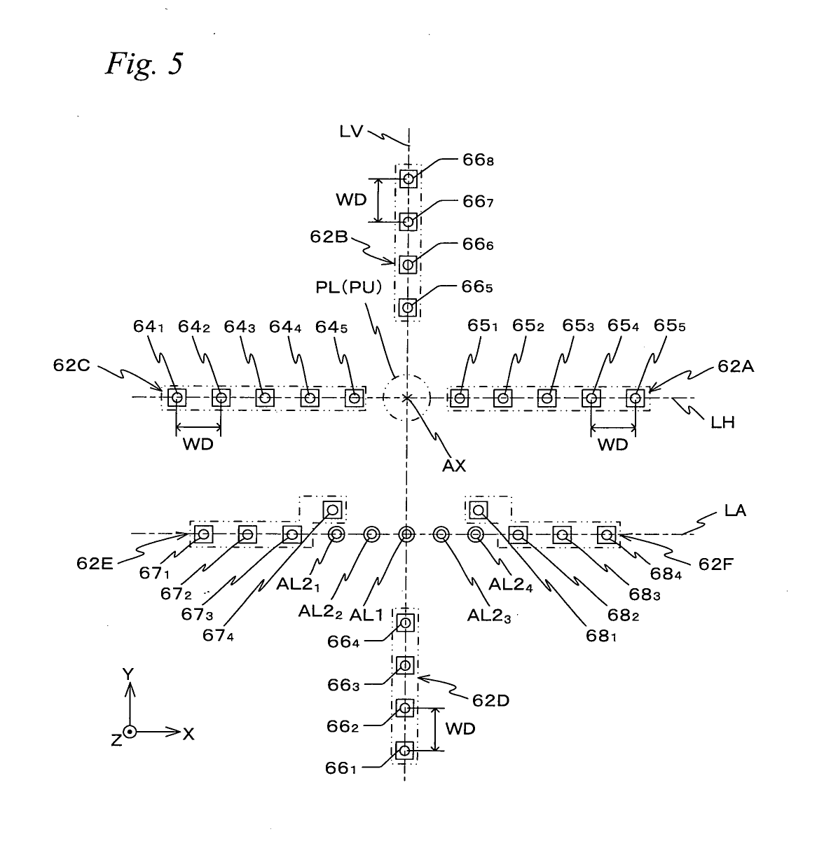

In exposure apparatus 100 of the present embodiment, as shown in FIGS. 4 and 5, a primary alignment system AL1 is provided whose detection center is placed at a position away by a predetermined distance to the −Y side from optical axis AX on a straight line (hereinafter, referred to as a reference axis) LV parallel to the Y-axis that passes through optical axis AX of projection optical system PL. Primary alignment system AL1 is fixed to a lower surface of the main frame (that includes the barrel surface plate previously described) which is not shown that holds projection unit PU. As shown in FIG. 5, on one side and the other side in the X-axis direction with primary alignment system AL1 in between, secondary alignment systems AL2₁, AL2₂ and secondary alignment systems AL2₃, AL2₄ are provided whose detection centers are place substantially symmetric to reference axis LV. Secondary alignment systems AL2₁ to AL2₄ are fixed to the lower surface of the main frame (not shown) via movable support members, and by driving mechanisms 60₁ to 60₄ (refer to FIG. 6), position of each of the detection areas in the X-axis direction can be adjusted.

In the present embodiment, for each of the alignment systems AL1, and AL2₁ to AL2₄, for example, an FIA (Field Image Alignment) system of an image processing method is used. Imaging signals from each of the alignment systems AL1, and AL2₁ to AL2₄ are supplied to main controller 20, via a signal processing system which is not shown.

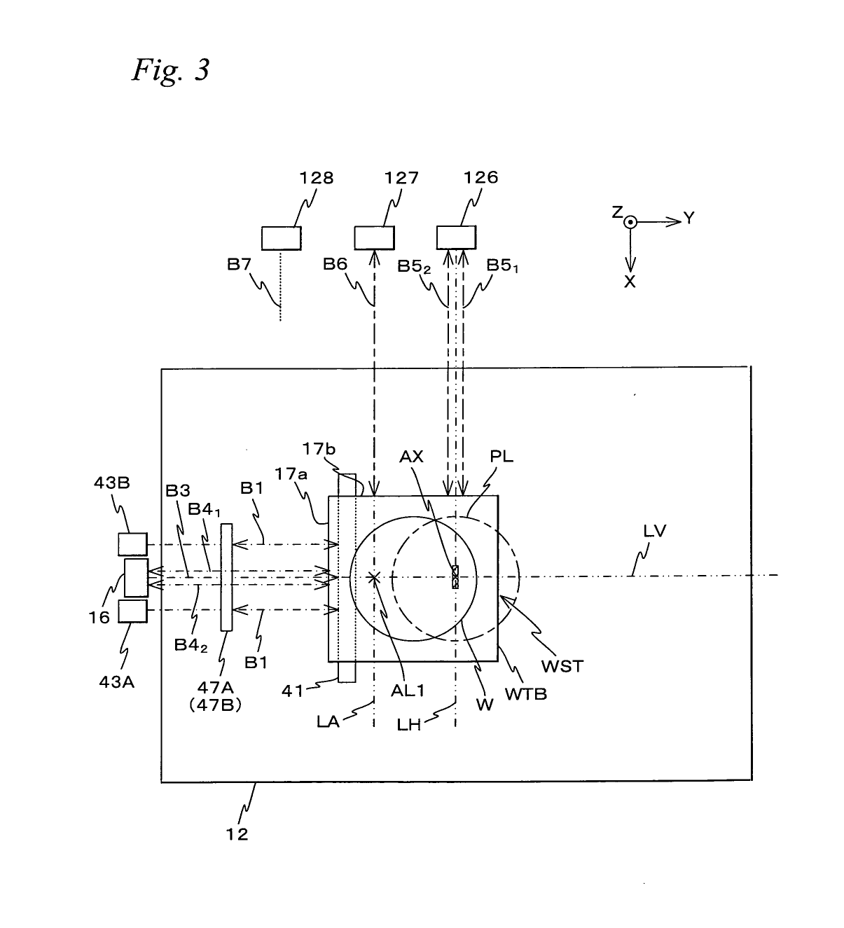

Interferometer system 118, as shown in FIG. 3, is equipped with a Y interferometer 16 and three X interferometers 126 to 128 that measure a position of wafer stage WST within the XY plane by each irradiating interferometer beams (measurement beams) on reflection surfaces 17a or 17b, and receiving reflected lights from reflection surfaces 17a or 17b. Y interferometer 16 irradiates at least three measurement beams parallel to the Y-axis, including a pair of measurement beams B4₁, B4₂ symmetric to reference axis LV, on reflection surface 17a and movable mirror 41 which will be described later on. Further, X interferometer 126, as shown in FIG. 3, irradiates at least three measurement beams parallel to the X-axis, including a pair of measurement beams B5₁, B5₂ symmetric to a straight line (hereinafter, referred to as a reference axis) LH which is parallel to the X-axis and is orthogonal to optical axis AX and reference axis LV, on reflection surface 17b. Further, X interferometer 127 irradiates at least two measurement beams parallel to the X-axis, including a measurement beam B6 whose measurement axis is a straight line (hereinafter, referred to as a reference axis) LA which is parallel to the X-axis and is orthogonal to reference axis LV at the detection center of primary alignment system AL1, on reflection surface 17b. Further, X interferometer 128 irradiates a measurement beam B7 parallel to the X-axis, on reflection surface 17b.

Position information from each of the interferometers described above of interferometer system 118 is supplied to main controller 20. Main controller 20 can also calculate rotation in the θx direction (that is, pitching), rotation in the θy direction (that is, rolling), and θz direction rotation (that is, yawing) in addition to the X, Y positions of wafer table WTB (wafer stage WST), based on measurement results of Y interferometer 16 and X interferometer 126 or 127.

Further, as shown in FIG. 1, a movable mirror 41 that has a concave-shaped reflection surface is attached to a side surface on the −Y side of stage main section 91. As it can be seen from FIG. 2, the length in the X-axis direction of movable mirror 41 is longer than reflection surface 17a of wafer table WTB.

Interferometer system 118 (refer to FIG. 6) is equipped, furthermore, with a pair of Z interferometers 43A, 43B that are placed facing movable mirror 41 (refer to FIGS. 1 and 3). Z interferometers 43A, 43B irradiate two measurement beams B1, B2 parallel to the Y-axis on movable mirror 41, respectively, and via movable mirror 41, irradiate the measurement beams B1, B2, respectively, on fixed mirrors 47A, 47B that are fixed, for example, to the main frame (not shown) holding projection unit PU. And, by receiving the respective reflected lights, optical path lengths of measurement beams B1, B2 are measured. From the measurement results, main controller 20 calculates the position of wafer stage WST in directions of four degrees of freedom (Y, Z, θy, θz).

In the present embodiment, position information (including rotation information in the θz direction) of wafer stage WST (wafer table WTB) within the XY plane is measured by main controller 20, mainly using encoder system 150 which will be described later on. Interferometer system 118 is used when wafer stage WST is positioned outside the measurement area of encoder system 150 (for example, in the vicinity of an unloading position and a loading position). Further, the system is used secondarily such as in the case when correcting (calibrating) a long-term variation (that occurs, for example, due to change of a scale over time and the like) of measurement results of encoder system 150. As a matter of course, interferometer system 118 and encoder system 150 can be used together, to measure all position information of wafer stage WST (wafer table WTB).

In exposure apparatus 100 of the present embodiment, independently from interferometer system 118, a plurality of head units that structure encoder system 150 are provided to measure the position of wafer stage WST within the XY plane in directions of three degrees of freedom (in each of the X-axis, the Y-axis, and the θz directions) (hereinafter, shortly referred to as a position (X, Y,θz) within the XY plane).

As shown in FIGS. 4 and 5, on the +X side, the +Y side, and the −X side of projection unit PU and the −Y side of primary alignment system AL1, four head units 62A, 62B, 62C, and 62D are placed, respectively. Further, head units 62E, 62F are provided on both sides in the X-axis direction on the outer side of alignment systems AL1, AL2₁ to AL2₄, respectively. Head units 62A to 62F are fixed in a state suspended from the main frame (not shown) which holds projection unit PU, via a support member. Incidentally, in FIG. 4, reference code UP indicates an unloading position where unloading of a wafer on wafer stage WST is performed, and reference code LP indicates a loading position where loading of a new wafer onto wafer stage WST is performed.

Head units 62A and 62C, as shown in FIG. 5, are equipped with a plurality of (five, in this case) Y heads 65₁ to 65₅ and Y heads 64₁ to 64₅ which are placed at an interval WD on reference axis LH previously described, respectively. Hereinafter, Y heads 65₁ to 65₅ and Y heads 64₁ to 64₅ will also be described as Y head 65 and Y head 64, respectively, when necessary.

Head units 62A, 62C, using Y scales 39Y₁, 39Y₂, structure multiple-lens Y linear encoders 70A, 70C (refer to FIG. 6) that measure the position of wafer stage WST (wafer table WTB) in the Y-axis direction (Y position). Incidentally, hereinafter, the Y linear encoder will be shortened, appropriately, to “Y encoder,” or “encoder”.

Head unit 62B, as shown in FIG. 5, is equipped with a plurality of (four, in this case) X heads 66₅ to 66₈ that are placed on the +Y side of projection unit PU, at interval WD on reference axis LV. Further, head unit 62D is equipped with a plurality of (four, in this case) X heads 66₁ to 66₄ that are placed on the −Y side of primary alignment system AL1, at interval WD on reference axis LV. Hereinafter, X heads 66₅ to 66₈ and X heads 66₁ to 66₄ will also be described as X head 66, as necessary.

Head units 62B, 62D, using X scales 39X₁, 39X₂, structure multiple-lens X linear encoders 70B, 70D (refer to FIG. 6) that measure the position of wafer stage WST (wafer table WTB) in the X-axis direction (X position). Incidentally, hereinafter, the X linear encoder will be shortened, appropriately, to “encoder”.

Here, interval WD in the X-axis direction of the five Y heads 65, 64 (to be more precise, irradiation points on the scale of measurement beams emitted by Y heads 65, 64) that head units 62A, 62C are equipped with, respectively, is decided so that at least one head constantly faces (irradiates a measurement beam on) the corresponding Y scales 39Y₁, 39Y₂ on exposure and the like. Similarly, interval WD in the Y-axis direction of adjacent X heads 66 (to be more precise, irradiation points on the scale of measurement beams emitted by X head 66) that head units 62B, 62D are equipped with, respectively, is decided so that at least one head constantly faces (irradiates a measurement beam on) the corresponding X scale 39X₁ or 39X₂, on exposure and the like.

Incidentally, the interval between X head 66₅ which is the outermost on the −Y side of head unit 62B and X head 66₄ which is the outermost on the +Y side of head unit 62D is set narrower than the width of wafer table WTB in the Y-axis direction, so that switching (joint) becomes possible between the two X heads by moving wafer stage WST in the Y-axis direction.

Head unit 62E is equipped with a plurality of (four, in this case) Y heads 67₁ to 67₄, as shown in FIG. 5.

Head unit 62F is equipped with a plurality of (four, in this case) Y heads 68₁ to 68₄. Y heads 68₁ to 68₄ are placed at positions symmetric to Y heads 67₁ to 67₄ about reference axis LV. Hereinafter, Y heads 67₁ to 67₄ and Y heads 68₁ to 68₄ will also be described as Y head 67 and Y head 68, respectively, as necessary.

On alignment measurement, at least one each of Y heads 67, 68 face Y scales 39Y₂, 39Y₁, respectively. Such Y heads 67, 68 (that is, Y encoders 70E, 70F (refer to FIG. 6) structured by these Y heads 67, 68) measure the Y position (and θz rotation) of wafer stage WST.

Further, in the present embodiment, at the time of base line measurement and the like of the secondary alignment system, Y heads 67₃, 68₂ respectively adjacent to secondary alignment systems AL2₁, AL2₄ in the X-axis direction, respectively face the pair of reference gratings 52 of FD bar 46, and by the pair of reference gratings 52 and Y heads 67₃, 68₂ facing the pair, the Y position of FD bar 46 is measured at the position of each reference grating 52. Hereinafter, the encoders structured by Y heads 67₃, 68₂ that respectively face the pair of reference gratings 52 will be referred to as Y linear encoders 70E₂, 70F₂. Further, for identification, the Y encoders structured by Y heads 67, 68 that face Y scales 39Y₂, 39Y₁ will be referred to as Y encoders 70E₁, 70F₁.

As the heads (64₁ to 64₅, 65₁ to 65₅, 66₁ to 66₈, 67₁ to 67₄, 68₁ to 68₄) of encoder 70A to 70F structuring encoder system 150 (refer to FIG. 6), a diffractive interference type encoder head is used which is disclosed such as in, for example, U.S. Pat. No. 7,238,931, U.S. Patent Application Publication No. 2008/0088843 and the like. Details on the diffractive interference type encoder head will be described later in the description.

Measurement values (position information) of encoders 70A to 70F described above are supplied to main controller 20. Main controller 20 calculates a position (X, Y, θz) of wafer stage WST within the XY plane, based on measurement values of three encoders from encoders 70A to 70D, or three encoders from encoders 70E₁, 70F₁, 70B and 70D.

Further, main controller 20 controls the rotation in the θz direction of FD bar 46 (wafer stage WST), based on measurement values of linear encoders 70E₂, 70F₂.

Besides this, in exposure apparatus 100 of the present embodiment, although it is not illustrated in FIG. 1, in the vicinity of projection unit PU, a multi-point focal point detection system consisting of an irradiation system 90a and a light receiving system 90b to detect a Z position of the wafer W surface at multiple detection points (hereinafter, shortly referred to as a “multi-point AF system”) is provided. As multi-point AF system, a multi-point AF system of an oblique-incidence method is employed that has a structure similar to the one disclosed in, for example, U.S. Pat. No. 5,448,332 and the like. Incidentally, irradiation system 90a and light receiving system 90b of multi-point AF system can be placed in the vicinity of head units 62A, 62B as is disclosed in, for example, U.S. Patent Application Publication No. 2008/0088843, and position information (surface position information) in the Z-axis direction of substantially the entire surface of wafer W can be measures (focus mapping can be performed) by simply scanning wafer W once in the Y-axis direction at the time of wafer alignment. In this case, it is desirable to provide a surface position measurement system that measures the Z position of wafer table WTB during this focus mapping.

FIG. 6 shows a block diagram of an input/output relation of main controller 20 which mainly structures a control system of exposure apparatus 100 that has overall control over the parts structuring each section. Main controller 20 includes a workstation (or a microcomputer) and the like, and has overall control over the parts structuring each section of exposure apparatus 100.

In exposure apparatus 100 of the present embodiment structured in the manner described above, according to a procedure similar to the one disclosed in an embodiment of, for example, U.S. Patent Application Publication No. 2008/0088843, a series of processing that uses wafer stage WST is executed by main controller 20 such as; unloading of wafer W at unloading position UP (refer to FIG. 4), loading of a new wafer W onto wafer table WTB at loading position LP (refer to FIG. 4), a first half processing of base line check of primary alignment system AL1 using fiducial mark FM of measurement plate 30 and primary alignment system AL1, resetting (reset) of an origin point of the encoder system and the interferometer system, alignment measurement of wafer W using alignment systems AL1, and AL2₁ to AL2₄, a second half processing of base line check of primary alignment system AL1 using aerial image measurement devices 45A, 45B, and exposure of a plurality of shot areas on wafer W by a step-and-scan method, based on position information of each shot area on the wafer obtained from results of alignment measurement and the latest base line of the alignment system.

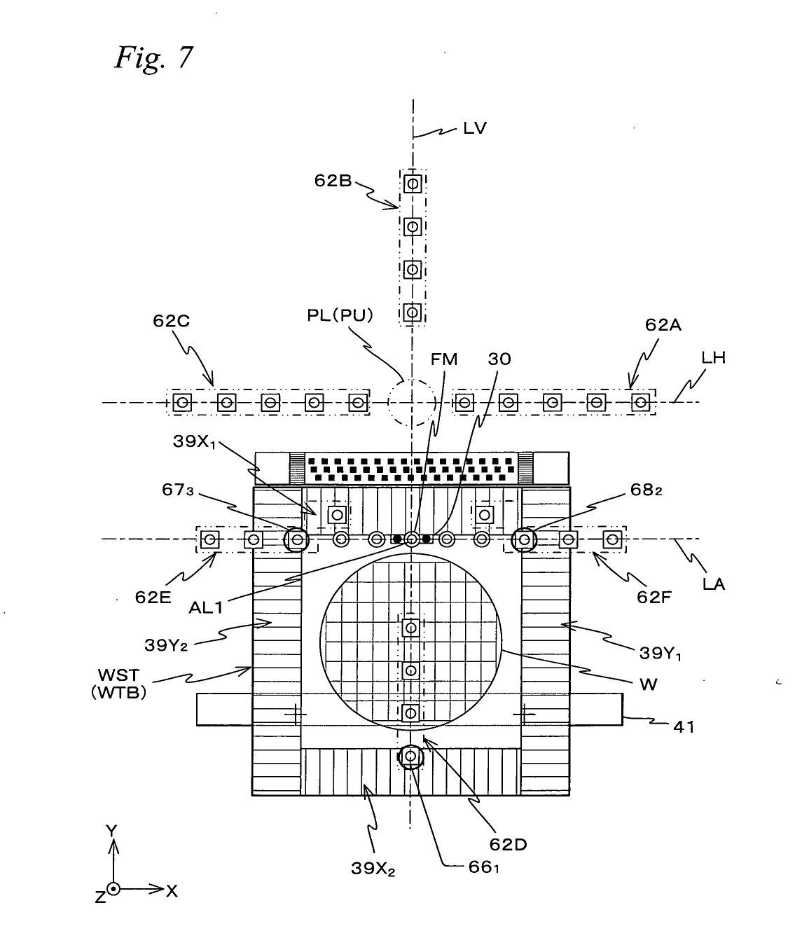

Here, alignment measurement (and base line check of the alignment system) of wafer W using alignment systems AL1, and AL2₁ to AL2₄ will be described. After the loading of wafer W, main controller 20 moves wafer stage WST to a position where fiducial mark FM on measurement plate 30 is positioned within a detection field of primary alignment system AL1 (that is, a position where the first half processing of base line measurement (Pri-BCHK) of the primary alignment system is performed), as shown in FIG. 7. Here, main controller 20 performs driving (position control) of wafer stage WST, based on encoder system 150, or to be more specific, measurement values of Y heads 67₃, 68₂ respectively facing Y scales 39Y₂, 39Y₁, and X head 66₁ facing X scale 39X₂ that are indicated circled in FIG. 7, respectively. Then, main controller 20 performs the first half processing of Pri-BCHK in which fiducial mark FM is detected, using primary alignment system AL1.

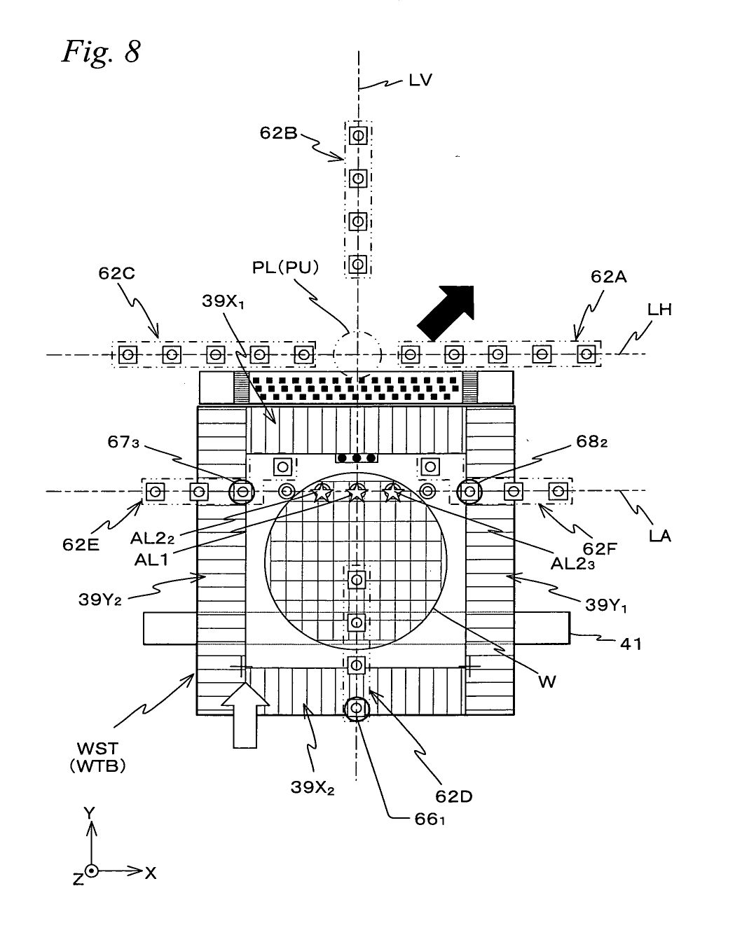

Next, as shown in FIG. 8, main controller 20 moves wafer stage WST in a direction indicated by an outlined arrow (+Y direction). Then, main controller 20 almost simultaneously and independently detects alignment marks arranged in three first alignment shot areas, as is indicated by star marks which are affixed in FIG. 8, using primary alignment system AL1 and secondary alignment systems AL2₂, AL2₃. Then, detection results of the three alignment systems AL1, AL2₂, and AL2₃ are associated with measurement results of encoder system 150 at the time of detection (that is, the X, the Y, and the θz positions of wafer table WTB), and are stored in an internal memory.

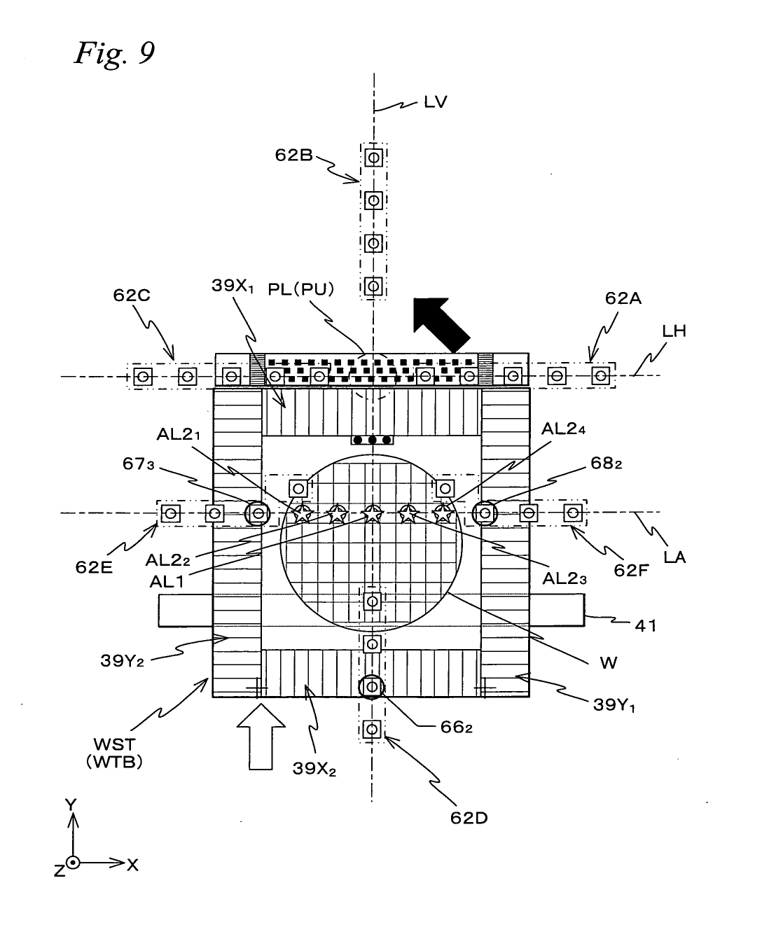

Next, as shown in FIG. 9, main controller 20 moves wafer stage WST in a direction indicated by an outlined arrow (+Y direction). Then, main controller 20 almost simultaneously and independently detects alignment marks arranged in five second alignment shot areas, as is indicated by star marks which are affixed in FIG. 9, using the five alignment systems AL1, and AL2₁ to AL2₄. Then, detection results of the five alignment systems AL1, and AL2₁ to AL2₄ are associated with measurement results of encoder system 150 at the time of detection (that is, the X, the Y, and the θz positions of wafer table WTB), and are stored in the internal memory.

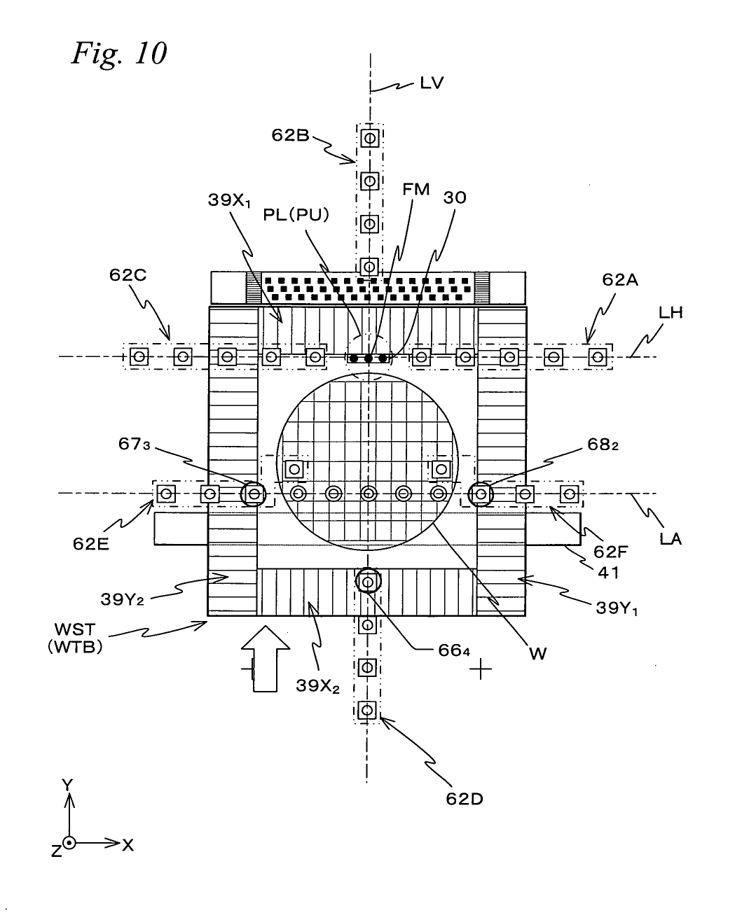

Next, main controller 20 moves wafer stage WST in the +Y direction, based on the measurement values of encoder system 150. Then, as shown in FIG. 10, when measurement plate 30 reaches an area directly below projection optical system PL, main controller 20 executes the second half processing of Pri-BCHK. Here, the second half processing of Pri-BCHK refers to a processing of measuring each of a projection image (aerial image) of a pair of measurement marks on reticle R projected by projection optical system PL, using aerial image measurement devices 45A, 45B previously described that includes measurement plate 30, in a method similar to the one disclosed in, for example, U.S. Patent Application Publication No. 2002/0041377 and the like, according to an aerial image measurement operation by a slit-scan method using each of a pair of aerial image measurement slit plates SL. And, storing the measurement results (aerial image intensity corresponding to the X, and the Y positions of wafer table WTB) in the internal memory. Main controller 20 calculates the base line of primary alignment system AL1, based on the results of the first half processing of Pri-BCHK and the results of the second half processing of Pri-BCHK that are described above.

Furthermore, main controller 20 sequentially performs step movement of wafer stage WST in the +Y direction, detects alignment marks arranged in five third alignment shot areas, and furthermore detects alignment marks arranged in three fourth alignment shot areas, and then associates the detection results with measurement results of encoder system 150 (that is, the X, the Y, and the θz positions of wafer table WTB) at the time of detection, and stores the results in the internal memory.

Main controller 20 calculates an array of all shot areas on wafer W and scaling (shot magnification) of the shot areas on a coordinate system defined by the measurement axes of encoder system 150 (in this case, an XY coordinate system that uses reference axis LV and reference axis LH as the coordinate axes), by performing a statistical calculation disclosed in, for example, U.S. Pat. No. 4,780,617 and the like, using the detection results of a total of 16 alignment marks obtained in the manner described above (two-dimensional position information) and the measurement results of the corresponding encoder system 150 (that is, the X, the Y, and the θz positions of wafer table WTB). Furthermore, by driving a specific movable lens structuring projection optical system PL, or by changing gas pressure inside an air-tight chamber formed between specific lenses structuring projection optical system PL based on the shot magnification that has been calculated, main controller 20 controls an adjustment device (not shown) that adjusts optical properties of projection optical system PL so that optical properties of projection optical system PL, such as, for example, projection magnification, are adjusted.

Then, based on results of wafer alignment (EGA) previously described that has been performed in advance and the latest base line of alignment systems AL1, and AL2₁ to AL2₄, main controller 20 performs exposure by a step-and-scan method, and sequentially transfers the reticle pattern onto a plurality of shot areas on wafer W. Hereinafter, a similar operation is repeatedly performed.

Incidentally, base line measurement of the secondary alignment systems AL2₁ to AL2₄ is performed similarly to the method disclosed in, for example, U.S. Patent Application Publication No. 2008/0088843, at an appropriate timing, by simultaneously measuring fiducial mark M on FD bar 46 within each field using alignment systems AL1, and AL2₁ to AL2₄, in a state where θz rotation of FD bar 46 (wafer stage WST) is adjusted, based on measurement values of encoders 70E₂, 70F₂ previously described.

In the present embodiment, main controller 20 can measure the position (X, Y, θz) within the XY plane, in an effective stroke area of wafer stage WST, or in other words, in an area where wafer stage WST moves for alignment and exposure operation, by using encoder system 150 (refer to FIG. 6).

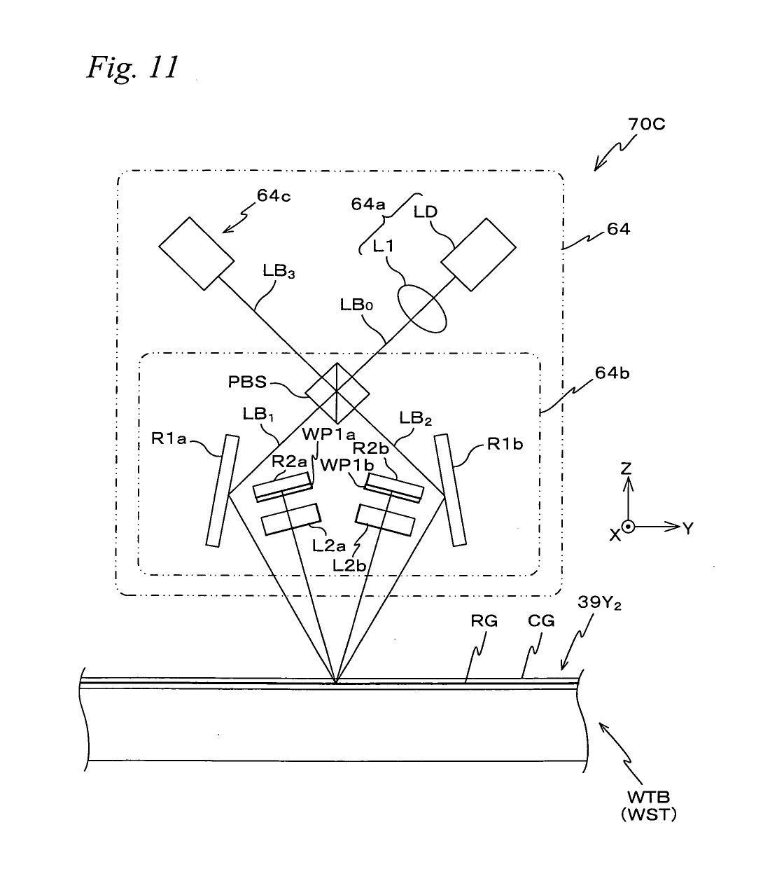

FIG. 11 shows a structure of encoder 70C, representing encoders 70A to 70F. Hereinafter, a structure, measurement principle and the like of the encoder will be described, referring to this encoder 70C (head unit 62C) as an example. Incidentally, in FIG. 11, a measurement beam is irradiated to Y scales 39Y₂ from Y head 64, which is a head of head unit 62C structuring encoder 70C.

Y head 64 is structured roughly from three sections which are irradiation system 64a, optical system 64b, and light receiving system 64c. Irradiation system 64a includes a light source that emits a laser beam LB₀, such as for example, a semiconductor laser LD, and a lens L1 placed on an optical path of laser beam LB₀. Optical system 64b is equipped with a polarization beam splitter PBS, a pair of reflection mirrors R1a, R1b, a pair of lenses L2a, L2b, a pair of quarter-wave plates (hereinafter, described as λ/4 plates) WP1a, WP1b, and a pair of reflection mirrors R2a, R2b and the like. Light receiving system 64c includes a polarizer (analyzer), a photodetector and the like.

Laser beam LB₀ emitted from semiconductor laser LD enters polarization beam splitter PBS via lens L1, and is split by polarization into two measurement beams LB₁, LB₂. Here, “split by polarization” means to split the incident beam into a P polarization component and an S polarization component. Measurement beam LB₁ which has passed through polarization beam splitter PBS reaches reflection diffraction grating RG formed on Y scales 39Y₂ via reflection mirror R1a, and measurement beam LB₂ reflected by polarization beam splitter PBS reaches reflection diffraction grating RG via reflection mirror R1b.

Diffraction beams of a predetermined order generated from reflection diffraction grating RG by irradiation of measurement beams LB₁, LB₂, such as for example, first order diffraction beams, after being converted into a circularly-polarized light by λ/4 plates WP1b, WP1a, via lenses L2b, L2a, respectively, are reflected by reflection mirrors R2b, R2a and pass through λ/4 plates WP1b, WP1a again, and head toward polarization beam splitter PBS following the same optical paths as the outward path in the opposite direction.

The direction of polarization of the two diffraction beams heading toward polarization beam splitter PBS rotates by 90 degrees from the original direction of polarization. Therefore, the diffraction beam deriving from measurement beam LB₁ having passed through polarization beam splitter PBS first is reflected by polarization beam splitter PBS. Meanwhile, the diffraction beam deriving from measurement beam LB₂ reflected first by polarization beam splitter PBS, passes through polarization beam splitter PBS and is condensed coaxially on the diffraction beam deriving from measurement beam LB₁. Then, these two diffraction beam are sent to light receiving system 64c as an output beam LB₃.

The two diffraction beams of output beam LB₃ sent to light receiving system 64c (to be more precise, S, P polarization components of output beam LB₃ deriving from measurement beams LB₁, LB₂, respectively) become interference lights, by the analyzer (not shown) inside light receiving system 64c which arranges the direction of polarization. Furthermore, as is disclosed in, for example, U.S. Patent Application Publication No. 2003/0202189 and the like, the interference light is branched into four lights. The four lights that are branched are received by the photodetector (not shown) after the phase being shifted by 0, π/2, π, 3π/2, respectively, converted into electrical signals corresponding to their respective light intensity (which are I₁, I₂, I₃, and I₄), and are sent to main controller 20 as an output of Y encoder 70C.

Main controller 20 obtains relative displacement ΔY between Y head 64 and Y scale 39Y₁ from the output of Y encoder 70C. Here, a calculation method of relative displacement ΔY in the present embodiment will be described in detail, including the calculation principle. For the sake of simplicity, a situation will be considered where intensity of measurement beams LB₁, LB₂ is equal to each other. In this situation, outputs I₁ to I₄ are expressed as follows.

I₁=A(1+cos(φ))∝I (1a)

I₂=A(1+cos(φ+π/2)) (1b)

I₃=A(1+cos(φ+π)) (1c)

I₄=A(1+cos(φ+3π/2)) (1d)

Here, φ is a phase difference between measurement beams LB₁, LB₂ (S, P polarization components of output beam LB₃ deriving from measurement beams LB₁, LB₂).

Main controller 20 obtains differences I₁₃, I₄₂ expressed as formulas (2a) and (2b) below from outputs I₁ to I₄.

I₁₃=I₁−I₃=2A cos(φ) (2a)

I₄₂=I₄−I₂=2A sin(φ) (2b)

Incidentally, differences I₁₃, I₄₂ can have an optical circuit (or an electric circuit) introduced within the photodetector, and differences I₁₃, I₄₂ can be optically (or electrically) obtained using the optical circuit (or an electric circuit).

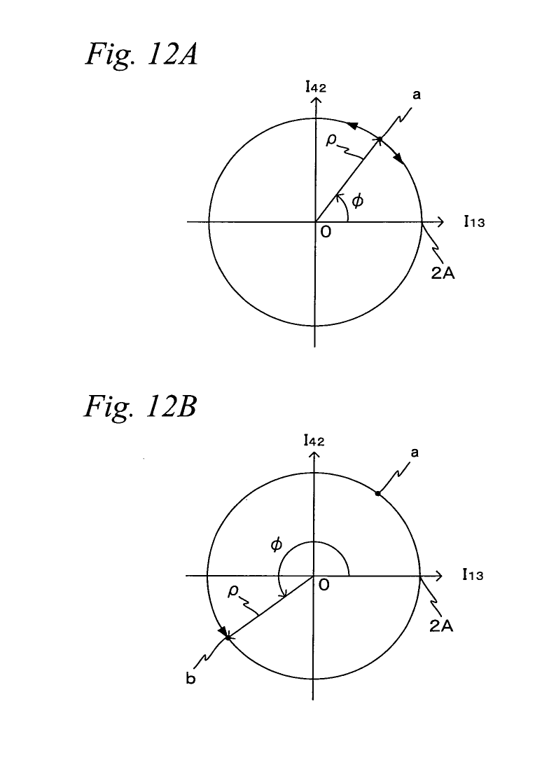

Here, movement of a point ρ(I₁₃, I₄₂) plotted on an orthogonal coordinate system shown in FIG. 12A will be considered, in order to explain a principle of correction of outputs I₁ to I₄ of Y encoder 70C (Y head 64). Incidentally, in FIGS. 12A and 12B, point ρ(I₁₃, I₄₂) is expressed using a vector ρ, and the phase of point ρ(I₁₃, I₄₂) is expressed as φ. The length of vector ρ, or in other words, the distance of point ρ(I₁₃, I₄₂) from an origin O is 2A.

In an ideal state, intensity I of interference light LB₃ is always constant. Accordingly, amplitude A of outputs I₁, I₂, I₃, and 4 is also always constant. Therefore, in FIG. 12A, point ρ(I₁₃, I₄₂) moves on a circumference of a circle whose distance (radius) from the origin point is 2A, with a change of intensity I of interference light LB₃ (that is, a change of outputs I₁ to I₄).

Further, in an ideal state, intensity I of interference light LB₃ varies sinusoidally, according to Y scales 39Y₁ (that is, wafer stage WST) being displaced in a measurement direction (period direction of the diffraction grating, that is, the Y-axis direction). Similarly, intensity I₁, I₂, I₃, and I₄ of the four branched lights vary sinusoidally, as is expressed respectively in formulas (1a), (1b), (1c), and (1d). In this ideal state, phase difference φ is equivalent to a phase φ of point ρ(I₁₃, I₄₂) in FIG. 12A. Phase difference φ (hereinafter referred to as phase unless differentiating is necessary in particular) varies in the following manner with respect to relative displacement ΔY.

φ(ΔY)=2πΔY/(p/4n)+φ₀ (3)

Here, p is a pitch of the diffraction grating that Y scale 39Y₁ has, n is a diffraction order (e.g., n=1), and φ₀ is a constant phase which is determined by a border condition (for example, a definition and the like of a reference position of displacement ΔY).

From formula (3), it can be seen that phase φ is not dependent on the wavelength of measurement beams LB₁, LB₂. Further, it can be seen that phase φ increases (decreases) by 2π each time displacement ΔY increases (decreases) by measurement unit p/4n. Accordingly, it can be seen that intensity I and outputs I₁, I₂, I₃, and I₄ of interference light LB₃ vibrate each time displacement ΔY increases or decreases by the measurement unit.

From the relation between phase φ and displacement ΔY expressed by formula (3) and the relation between outputs to I₄ expressed by formulas (1a) to (1d) and phase φ (that is, relations between differences I₁₃, I₄₂ and displacement ΔY), point ρ(I₁₃, I₄₂) rotates counterclockwise on the circumference of the circle whose radius is 2A, for example, from point a to point b as shown in FIG. 12B, according to the increase of displacement ΔY. On the contrary, according to the decrease of displacement ΔY, point ρ(I₁₃, I₄₂), rotates clockwise on the circumference described above. And, point ρ(I₁₃, I₄₂) circles the circumference each time displacement ΔY increases (decreases) by the measurement unit.

Therefore, main controller 20 counts the number of times point ρ(I₁₃, I₄₂) circles the circumference, with a reference phase (for example, constant phase φ₀) which is decided in advance serving as a reference. This number of times of circling is equivalent to the number of vibrations of intensity I of interference light LB₃. This countable number of values (count value) will be expressed as c_{ΔY}. Furthermore, main controller 20 obtains displacement φ′=φ−φ₀ of a phase of point ρ(I₁₃, I₄₂) with respect to the reference phase. From such count value c_{ΔY} and phase displacement φ′, a measurement value C_{ΔY} of displacement ΔY can be obtained as follows.

C_{ΔY}=(p/4n)×(c_{ΔY}+φ′/2π) (4)

Here, constant phase φ₀ will serve as a phase offset (however, defined as 0≦φ₀<2π), and phase φ (ΔY=0) at the reference position of displacement ΔY is to be held.

As is obvious from the description so far, Y encoder 70C has a measurement period equivalent to measurement unit λ=p/4n.

Incidentally, a proportionate relation between phase φ and displacement ΔY may no longer exist, for example, due to an interference occurring with a stray light and the like. In this case, while outputs I₁ to I4 may appear to be ideal as is described above, a period error equal to the measurement period may occur with respect to measurement value C_{ΔY} of displacement ΔY. Further, when outputs I₁ to I4 deviate from an ideal output, because a calculation error of phase φ occurs, a period error equal to the measurement period may occur. Such period errors equal to the measurement period will be collectively referred to as a periodic error.

Other heads within head unit 62C, and heads 65, 66, 67, and 68 that head units 62A, 62B, 62D, 62E, 62F are equipped with, respectively, are structured similarly to Y head 64 (encoder 70C).

Further, in the present embodiment, by employing the placement of encoder heads previously described, at least one X head 66 constantly faces X scales 39X₁ or 39X₂, at least one Y head 65 (or 68) constantly faces Y scale 39Y₁, and at least one Y head 64 (or 67) constantly faces Y scale 39Y₂, respectively. From the encoder heads facing the scales, measurement results of intensity I₁, I₂, I₃, and I₄ of the branched lights described above are supplied to main controller 20. Main controller 20 obtains displacement of wafer stage WST (to be more precise, displacement of the scale on which the measurement beam is projected) in a measurement direction of each head from measurement results I₁, I₂, I₃, and I₄ that have been supplied. Results that are obtained are to be treated as measurement values of encoders 70A, 70C, and 70B or 70D (or encoders 70E₁, 70F₁, and 70B or 70D) described above.

Main controller 20 calculates the position (X, Y, θz) of wafer stage WST within the XY plane, based on at least three measurement results of linear encoders 70A to 70D. Here, measurement values of X head 66 and Y heads 65, 64 (to be described as C_{X}, C_{Y1}, and C_{Y2}, respectively) are dependent as in the following formulas (5a) to (5c), with respect to the position (X, Y, θz) of wafer stage WST within the XY plane.

C_{X}=(p_{X}−X)cos θz+(q_{X}−Y)sin θz (5a)

C_{Y1}=−(p_{Y1}−X)sin θz+(q_{Y1}−Y)cos θz (5b)

C_{Y2}=−(p_{Y2}−X)sin θz+(q_{Y2}−Y)cos θz (5c)

However, (p_{X}, q_{X}), (p_{Y1}, q_{Y1}), (p_{Y2}, q_{Y2}) are X, Y installation positions of X head 66, Y head 65, and Y head 64 (to be more precise, X, Y positions of projection points of the measurement beams), respectively. Therefore, main controller 20 substitutes measurement values C_{X}, C_{Y1}, and C_{Y2} of the three heads into formulas (5a) to (5c), and by solving simultaneous equations (5a) to (5c) after the substitution, calculates the position (X, Y, θz) of wafer stage WST within the XY plane. Based on the calculation results, drive (position control) of wafer stage WST is performed.

Further, main controller 20 controls rotation in the θz direction of FD bar 46 (measurement stage MST), based on measurement values of linear encoders 70E₂, 70F₂. Here, measurement values of linear encoders 70E₂, 70F₂ (to be described as C_{Y1}, C_{Y2}, respectively) are dependent as in the following formulas (5b) (5c), with respect to position (X, Y, θz) of FD bar 46 within the XY plane. Accordingly, the θz position of FD bar 46 can be obtained as in the following formula (6), from measurement values C_{Y1}, C_{Y2}.

sin θz=−(C_{Y1}−C_{Y2})/(p_{Y1}−p_{Y2}) (6)

However, q_{Y1}=q_{Y2} was assumed for the sake of simplicity.

On alignment measurement performed in exposure apparatus 100 of the present embodiment, as previously described, position of wafer stage WST is measured using encoder system 150 (or interferometer system 118), and by driving wafer stage WST based on the measurement results, the alignment marks subject to detection are positioned and detected within the detection field of alignment systems AL1, and AL2₁ to AL2₄. By performing statistical calculation using the detection results and measurement results of encoder system 150 at the time of detection (that is, measurement results of the XYθz position of wafer stage WST), an array and the like of the shot areas on wafer W is calculated. Here, in encoder system 150 (and interferometer system 118), an error (periodic error) may occur in a period equivalent to a measurement period (measurement unit λ). The measurement period, as an example, is 250 nm for encoder system 150 (as an example, around 160 nm for interferometer system 118). On the other hand, while the alignment marks are designed to be formed at the same position in every wafer, because the mounting position on wafer stage WST varies, for example, at an accuracy of several μm to several tens of μm each time the wafer is mounted, the position of the alignment marks on the position measurement coordinate system of wafer stage WST may also vary each time the position is measured. Therefore, by periodic errors of encoder system 150, detection reproducibility of the alignment marks deteriorates, which reduces the measurement accuracy of alignment measurement, which in turn causes alignment errors of the wafer.

Here, an alignment mark detection method for avoiding the influence of periodic errors of encoder system 150 (or interferometer system 118) described above will be described.

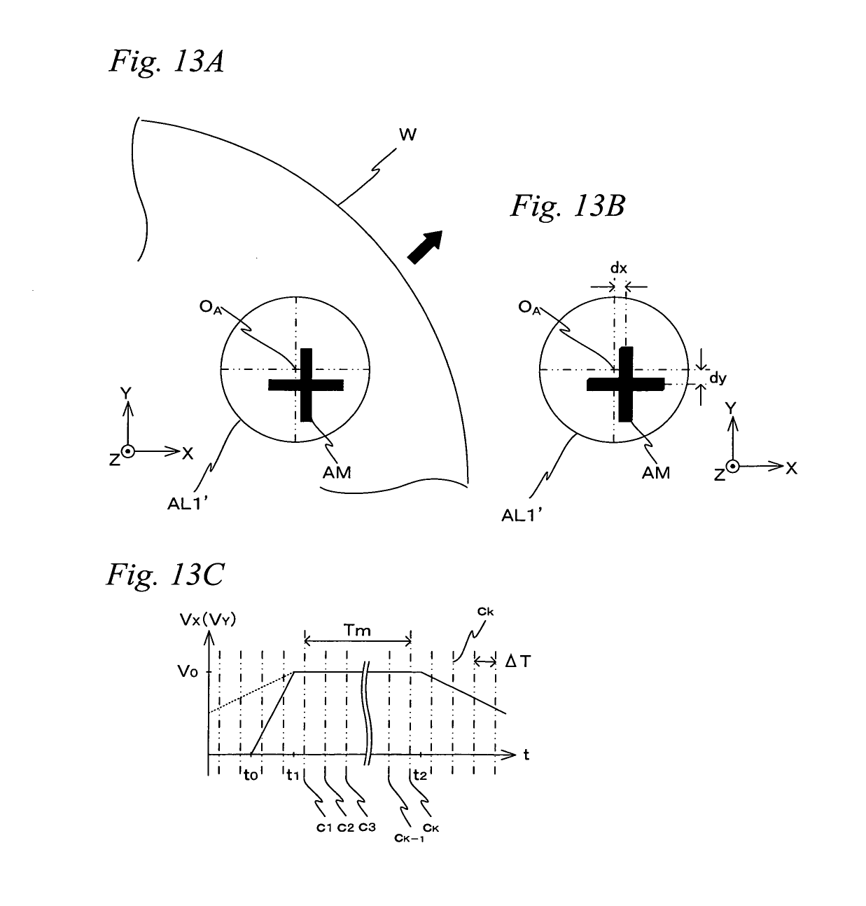

As shown in FIG. 13A, main controller 20 drives wafer stage WST based on measurement results of encoder system 150, and positions alignment mark AM subject to detection within a detection field AL1′ of an alignment system (in this case, primary alignment system AL1 as an example).

After the positioning, main controller 20 drives wafer stage WST in a measurement direction of encoder system 150, such as for example, in the X-axis direction (or the Y-axis direction). As is shown using a solid line in FIG. 13C, this increases velocity Vx(Vy) of wafer stage WST from a drive starting time t₀ to t₁, and at time t₁, wafer stage WST reaches a predetermined velocity V₀. After this, main controller 20 maintains velocity Vx(Vy) of wafer stage WST to V₀, that is, performs a constant velocity drive of wafer stage WST.

During the constant velocity drive of wafer stage WST, main controller 20 picks up an image of alignment mark AM using primary alignment system AL1, during a predetermined imaging time Tm. During the imaging, a measurement result (X_{X}, Yₖ, θzₖ) of encoder system 150 is collected for each measurement clock cₖ which occurs at a predetermined time interval ΔT. In an example shown in FIG. 13C, the measurement result (Xₖ, Yₖ, θzₖ) is collected at the time of generation of measurement clock cₖ (k=1 to K).

When imaging time Tm has passed, and wafer stage WST has moved by a distance Lm (=nλ), which is an integral multiple of n times the measurement period (measurement unit λ), main controller 20 finishes the imaging of alignment mark AM. Accordingly, as shown in FIG. 13B, alignment mark AM which is blurred by moving distance Lm is imaged. Incidentally, in FIG. 13B, illustration of wafer W is omitted.

Main controller 20 obtains position (detection position) dx, dy of alignment mark AM, with detection center O_{A} of primary alignment system AL1 serving as a reference, using imaging results described above. Further, main controller 20 determines that an average X₀=Σₖ Xₖ/K, Y₀=Σₖ Yₖ/K of K measurement results Xₖ, Yₖ which are collected during the imaging should be a position measurement result of wafer stage WST at the time of detection of alignment mark AM. dx, dy, X₀, Y₀ which are obtained are to be the detection results of alignment mark AM.

Main controller 20 detects the alignment marks similarly, also in the case of using secondary alignment systems AL2₁ to AL2₄.

According to the procedure described so far, in position measurement result X₀(Y₀) of wafer stage WST at the time of detection of alignment mark AM, a periodic error of encoder system 150 in a direction of constant velocity drive of wafer stage WST, or in other words, in the X-axis direction (the Y-axis direction), is reduced due to an averaging effect.

Incidentally, in the description above, while wafer stage WST was driven in the X-axis direction (or the Y-axis direction) during the imaging of alignment mark AM, in the case periodic errors of encoder system 150 are generated in both the X-axis direction and the Y-axis direction, wafer stage WST is to be driven in both the X-axis direction and the Y-axis direction by a distance (n_{X}λ_{X}, n_{y}λ_{y}) which is an integral multiple of (n_{X}, n_{y}) times the measurement period (λ_{X}, λ_{y}) respectively. For example, in the case the measurement period is equal in the X-axis direction and the Y-axis direction, respectively, (λ_{X}=λ_{y}), n_{X}=n_{y} is selected, and as shown in FIG. 13A, wafer stage WST is driven in a direction (direction indicated by a blackened arrow) that forms an angle by 45 degrees in the X-axis direction and the Y-axis direction, respectively.

Further, also in the case alignment measurement (detection of alignment marks) is a one-dimensional measurement in only the X-axis direction or the Y-axis direction, during the imaging of alignment mark AM, wafer stage WST is driven in both the X-axis direction and the Y-axis direction by a distance which is an integral multiple times the measurement period, respectively. In exposure apparatus 100 of the present embodiment, as is previously described, because the position (X, Y, θz) of wafer stage WST within the XY plane is calculated using three measurement results of linear encoder 70A to 70D, for example, a periodic error of linear encoder 70B whose measurement direction is in the X-axis direction affects measurement results of the Y position of wafer stage WST.

Further, driving distance (driving distance in the individual measurement directions) Lm of wafer stage WST during the imaging of the alignment mark is to be around the same level or less than the detection resolution of alignment systems AL1, and AL2₁ to AL2₄. Otherwise, an image blur of alignment mark AM will provide an error that cannot be ignored with respect to the detection results. In alignment systems AL1, and AL2₁ to AL2₄ used in exposure apparatus 100 of the present embodiment, resolution of the imaging element (CCD) that each system is equipped with, or in other words, the size of one pixel is around 200 nm, which is around the same level or less than measurement period λ of encoder system 150 and interferometer system 118. Accordingly, if n=1 is selected in moving distance Lm (=nλ), the influence of image blur with respect to the detection results can be sufficiently ignored.

Further, in order to reduce the influence of periodic errors of encoder system 150 on alignment measurement due to averaging effect, the generation interval of measurement clock cₖ with respect to imaging time Tm should be shortened so as to collect many measurement results (Xₖ, Yₖ, θZₖ), and such measurement results should be averaged. Here, in exposure apparatus 100 of the present embodiment, for example, since Tm= 1/60 sec and the generation period of measurement clock cₖ is 10 kHz, around 160 measurement results are collected. Accordingly, reduction of the influence of periodic errors due to averaging effect can be sufficiently expected.

Further, driving velocity V₀ of wafer stage WST is defined to V₀=nλ/Tm, from driving distance nλ and imaging time Tm. Here, when the constant velocity drive of wafer stage WST is disturbed, an asymmetric distortion occurs in the image of the alignment mark that is imaged, and the position measurement result X₀, Y₀ of wafer stage WST at the time of detection also vary. These cause errors in alignment measurement. Therefore, the position measurement results of wafer stage WST are collected and their distribution within measurement period λ monitored, or velocity Vx, Vy is calculated and their dispersion monitored, during the imaging of the alignment mark. In the case it is judged that the constant velocity drive of wafer stage WST is disturbed such as when the distribution of position measurement results. appears to be biased, dispersion of velocity is large and the like, for example, alignment measurement should be executed again.

Further, imaging timing of the alignment mark and collecting timing of measurement results of encoder system 150 are made to be synchronous. For example, as shown in FIG. 13C, the imaging of the alignment mark begins simultaneously with generation of measurement clock c₁, and the imaging of the alignment mark is finished simultaneously with the generation of measurement clock cₖ. In the case this synchronization is not established, an error in alignment measurement occurs which is about the same level as the distance that wafer stage WST moves during generation interval ΔT of measurement clock cₖ. The moving distance, for example, is 1. 5 nm, with respect to Tm= 1/60 sec, constant velocity driving distance Lm=250 nm, and generation period of measurement clock cₖ 1/ΔT=10 kHz. This distance cannot be ignored with respect to overlay accuracy required in exposure apparatus 100 of the present embodiment. Therefore, for example, to the required overlay accuracy 0. 15 nm, synchronization is to be established at least at an accuracy of 10 μsec. Further, in connection with reversing the driving direction (alternate scanning) of wafer stage WST to be described later on, synchronization is to be established not only at the beginning but also at the finishing when the alignment mark is imaged. This allows synchronization to be established, regardless of the driving direction.

Incidentally, in the alignment system, it is preferable for signal intensity of a detection signal of the alignment mark to be stable. For example, when the intensity of the detection signal changes over time due to flickering and the like of the illumination light that illuminates the alignment mark, measurement turns out to be selective at a time when the detection signal is strong, which may cause a difference between the measurement of stage position obtained as a uniform average. For example, when considering the case of an illumination light including an illumination flickering of a single frequency, in the case amplitude of the detection signal is around 0.1%, a measurement error on alignment can be suppressed to around 0.1 nm. Further, when vibration period of the detection signal is sufficiently small with respect to the imaging time, influence of the vibration can be reduced. For example, in the case of performing imaging of 60 frames per second, even if intensity variation of the detection signal is 1%, in the case variation frequency is 600 Hz (ten times the frame rate), measurement errors of alignment can be suppressed to around 0.1 nm.

Further, as is previously described, on alignment measurement in exposure apparatus 100 of the present embodiment, a maximum of five alignment marks arranged in the X-axis direction are detected simultaneously, using alignment systems AL1, and AL2₁ to AL2₄, while moving wafer stage WST in the +Y direction. Therefore, each time detection is performed, the driving direction of wafer stage WST in the X-axis direction should be reversed. For example, as shown in FIG. 8, when detecting the alignment marks arranged in the first alignment shot area, wafer stage WST is to be driven in constant velocity in a direction by an angle of 45 degrees to the X-axis direction and the Y-axis direction (direction indicated by a blackened arrow). Further, as shown in FIG. 9, when detecting the alignment marks arranged in the second alignment shot area, wafer stage WST is to be driven in constant velocity in a direction by an angle of 135 degrees to the X-axis direction and 45 degrees to the Y-axis direction (direction indicated by a blackened arrow). When detecting the alignment marks arranged in the third alignment shot area, wafer stage WST is to be driven uniformly in a direction by an angle of 45 degrees to the X-axis direction and the Y-axis direction (direction indicated by a blackened arrow), and on detecting the alignment marks arranged in the fourth alignment shot area, wafer stage WST is to be driven in constant velocity in a direction by an angle of 135 degrees to the X-axis direction and 45 degrees to the Y-axis direction (direction indicated by a blackened arrow). This allows successive detection of alignment marks without returning wafer stage WST back to the starting position for the constant velocity drive, which can reduce the time required for alignment measurement.

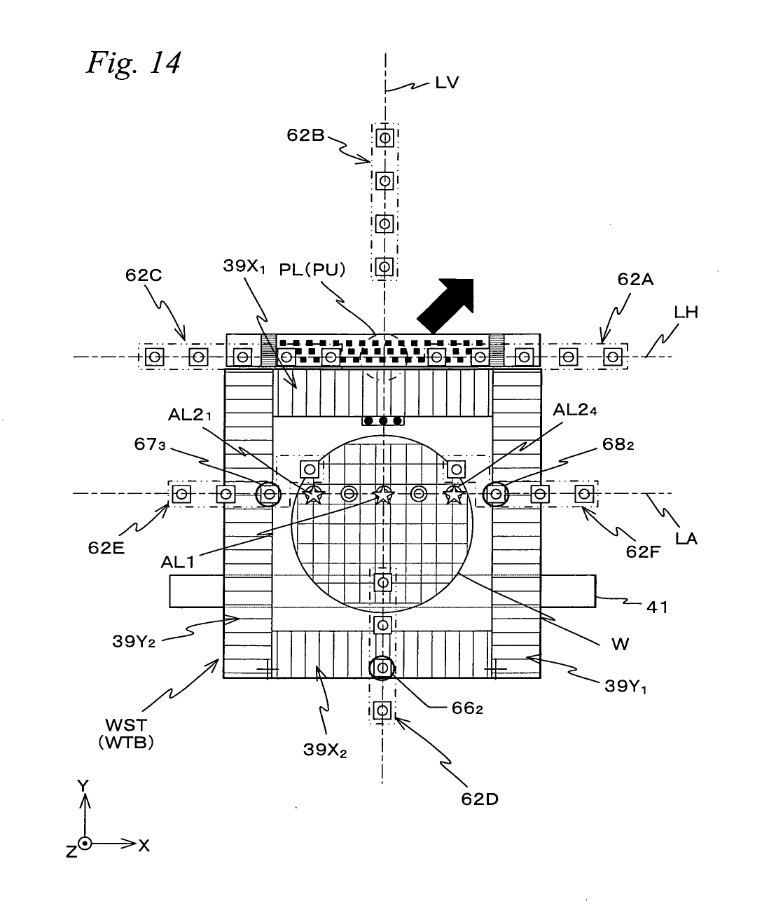

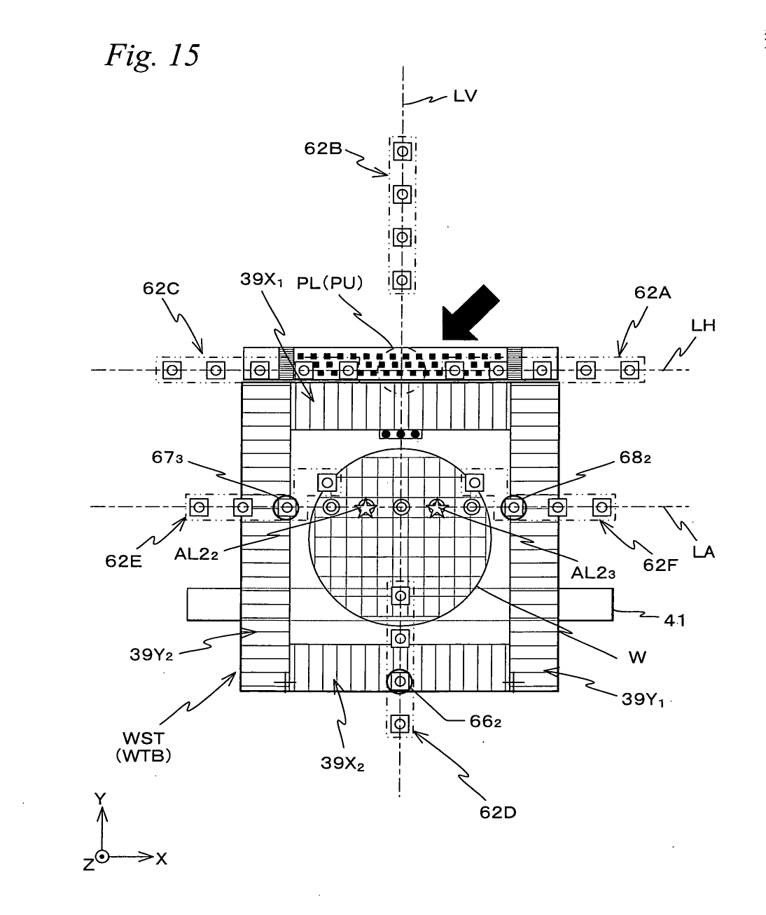

Further, when detection of the five alignment marks arranged in the X-axis direction using alignment systems AL1, and AL2₁ to AL2₄ is to be performed in a few times due to unevenness of the wafer surface, or focus error between alignment systems AL1, and AL2₁ to AL2₄, due to unevenness of the wafer surface, or focus error (or accuracy of focusing) and the like, an alignment mark detection method by an alternate scanning method should be employed. For example, as shown in FIG. 14, in the first detection, three corresponding alignment marks are to be detected, using alignment systems AL1, AL2₁, and AL2₄. Here, wafer stage WST is driven in a direction by an angle of 45 degrees to the X-axis direction and the Y-axis direction, respectively (direction indicated by a blackened arrow). In the second detection, as shown in FIG. 15, two corresponding alignment marks are detected, using alignment systems AL2₂, and AL2₃. Here, the driving direction is reversed, and wafer stage WST is driven in a direction indicated by a blackened arrow. That is, each time detection of the alignment mark is performed, the driving direction of wafer stage WST is reversed. This allows alignment marks to be detected successively without making wafer stage WST return to the starting position for the constant velocity drive each time detection is performed, which can reduce the time required for alignment measurement.

Further, in the earlier description, when an alignment mark subject to detection was detected as in FIG. 13C where velocity Vx(Vy) is indicated using a solid line, while the constant velocity drive of wafer stage WST was performed after the alignment mark was positioned within the detection field of the alignment system, the positioning is not always necessary, as is shown using a broken line.

As is described in detail so far, in exposure apparatus 100 of the present embodiment, alignment marks provided on wafer W are imaged using alignment systems AL1, and AL2₁ to AL2₄, while driving wafer stage WST based on measurement results of encoder system 150, and positions of the alignment marks are obtained, using the imaging position of the alignment marks obtained from the imaging results and the position of wafer stage WST at the time of imaging obtained from the measurement results of encoder system 150. Here, during the imaging of alignment marks, wafer stage WST is driven in constant velocity by a moving distance which is an integral multiple times the measurement period of encoder system 150, and the position of wafer stage WST at the time of imaging is also obtained from an average of position measurement results of encoder system 150. This allows the alignment measurement to be performed with good precision, without being influenced by periodic errors of encoder system 150.

Further, because mark detection (alignment measurement) with high precision can be performed in the manner described above, by driving wafer stage WST and aligning wafer W based on such mark detection results, exposure with high precision becomes possible.

Further, as a method similar to the alignment mark detection method of the present embodiment, there is a step detection method in which alignment marks are detected by changing the position of wafer stage WST, or in other words, changing a plurality of positioning positions of alignment marks, and using an average of these results as detection results. However, to reduce the influence of periodic errors, the number of times of detection has to be increased, which has a drawback of making the detection time longer. On the other hand, because the detection method of the present embodiment performs detection only once, except that it requires time for acceleration/deceleration of wafer stage WST, the method shows remarkable results in reducing the detection time.

Incidentally, in the alignment measurement of the present embodiment, while the position of the alignment mark was obtained using measurement results of the position of wafer stage WST measured by encoder system 150 at the time of imaging as an example, the present invention is not limited to this, and a similar detection method can be applied also in the case when the position of wafer stage WST at the time of imaging is measured using not only interferometer system 118, but also other measurement systems that can generate a periodic error, and the position of the alignment mark is obtained using the measurement results. Further, also in the case of using different measurement systems as the position measurement system used for drive (position control) of wafer stage WST and the position measurement system of wafer stage WST used for alignment measurement, a similar detection method can be applied.

Further, while the mark detection method of the present embodiment was applied in the case of detecting alignment marks provided on a wafer, the present invention is not limited to this, and can also be applied in the case of detecting a mark such as a fiducial mark FM and the like, which is provided on wafer stage WST.

Further, it is a matter of course that the structure of each measurement device such as the encoder system described above in the embodiment is a mere example. For example, in the embodiment above, while an example was given of a case where an encoder system was employed having a structure in which a grating section (Y scales, X scales) was provided on the wafer table (wafer stage), and X head, Y head were placed outside of the wafer stage facing the grating section, other than this, as disclosed in, for example, U.S. Patent Application Publication No. 2006/0227309, an encoder system which is structured having an encoder head provided on a wafer stage, and a grating section (for example, a two-dimensional grating or a one-dimensional grating section placed two-dimensionally) placed outside of the wafer stage, can be employed. The encoder head is not limited to a one-dimensional head, and as a matter of course, can be a two-dimensional head with a measurement direction in the X-axis direction and the Y-axis direction, or a sensor head having a measurement direction in one of the X-axis direction and the Y-axis direction and the Z-axis direction. As the latter sensor head, a displacement measurement sensor head whose details are disclosed in, for example, U.S. Pat. No. 7,561,280, can be used.

Further, in the embodiment described above, while the case has been described where the exposure apparatus is a dry type exposure apparatus which performs exposure of wafer W without liquid (water), the present invention is not limited to this, and the embodiment described above can also be applied to an exposure apparatus disclosed in, for example, European Patent Application Publication No. 1420298, PCT International Publication No. 2004/055803, U.S. Pat. No. 6,952,253 and the like, which has a liquid immersion space including an optical path of the illumination light formed in between a projection optical system and a wafer, and exposes a wafer via the projection optical system and the liquid of the liquid immersion space with the illumination light. Further, the embodiment described above can also be applied to a liquid immersion exposure apparatus and the like, disclosed in, for example, U.S. Patent Application Publication No. 2008/0088843.

Further, in the embodiment described above, while the case has been described where the exposure apparatus is a scanning type exposure apparatus of a step-and-scan method and the like, the present invention is not limited to this, and the embodiment described above can also be applied to a static type exposure apparatus such as a stepper. Further, the embodiment described above can also be applied to a reduction projection exposure apparatus which employs a step-and-stitch method where a shot area and a shot area are synthesized, an exposure apparatus of a proximity method, or a mirror projection aligner and the like. Furthermore, as disclosed in, for example, U.S. Pat. No. 6,590,634, U.S. Pat. No. 5,969,441, U.S. Pat. No. 6,208,407 and the like, the embodiment described above can also be applied to a multi-stage type exposure apparatus equipped with a plurality of wafer stages. Further, as is disclosed in, for example, U.S. Pat. No. 7,589,822 and the like, the embodiment described above can be applied to an exposure apparatus which is equipped with a measurement stage including a measurement member (for example, a fiducial mark, and/or a sensor and the like), separate from the wafer stage.

Further, the projection optical system of the exposure apparatus in the embodiment described above is not limited to a reduction system, and can either be an equal magnifying or a magnifying system, and projection optical system PL is not limited to the refractive system, and can also either be a reflection system and catodioptric system, and the projection image can either be an inverted image or an upright image. Further, while the shape of the illumination area and the exposure area previously described was rectangular, the shape is not limited to this, and can be, for example, a circular arc, a trapezoid, or a parallelogram and the like.

Incidentally, the light source of the exposure apparatus in the embodiment described above is not limited to the ArF excimer laser, and a pulse laser light source such as a KrF excimer laser (output wavelength 248 nm), an F₂ laser (output wavelength 157 nm), an Ar₂ laser (output wavelength 126 nm), a Kr₂ laser (output wavelength 146 nm) and the like, or a super high pressure mercury lamp which emits a g-line (wavelength 436 nm), an i-line (wavelength 365 nm) and the like can also be used. Further, a harmonic generator of a YAG laser and the like can also be used. Besides this, a harmonic wave, which is obtained by amplifying a single-wavelength laser beam in the infrared or visible range emitted by a DFB semiconductor laser or fiber laser as vacuum ultraviolet light, with a fiber amplifier doped with, for example, erbium (or both erbium and ytterbium), and by converting the wavelength into ultraviolet light using a nonlinear optical crystal, can also be used, as is disclosed in, for example, U.S. Pat. No. 7,023,610.

Further, in the embodiment above, illumination light IL of the exposure apparatus is not limited to the light having a wavelength equal to or more than 100 nm, and it is needless to say that the light having a wavelength less than 100 nm can be used. For example, in recent years, in order to expose a pattern equal to or less than 70 nm, an EUV exposure apparatus that generate an EUV (Extreme Ultraviolet) light in a soft X-ray range (e.g. a wavelength range from 5 to 15 nm) using an SOR or a plasma laser as a light source, and uses a total reflection reduction optical system designed under the exposure wavelength (e.g. 13.5 nm) and the reflective mask has been developed. In this apparatus, the arrangement in which scanning exposure is performed by synchronously scanning a mask and a wafer using a circular arc illumination can be considered, and therefore, the embodiment described above can also be suitably applied to such apparatus. Besides such an apparatus, the embodiment described above can also be applied to an exposure apparatus that uses charged particle beams such as an electron beam or an ion beam.

Further, in the embodiment described above, while a light transmissive type mask (reticle) in which a predetermined light-shielding pattern (or a phase pattern or a light-attenuation pattern) is formed on a light-transmitting substrate is used, instead of this reticle, as disclosed in, for example, U.S. Pat. No. 6,778,257, an electron mask (which is also called a variable shaped mask, an active mask or an image generator, and includes, for example, a DMD (Digital Micro-mirror Device) that is a type of a non-emission type image display element (spatial light modulator) or the like) on which a light-transmitting pattern, a reflection pattern, or an emission pattern is formed according to electronic data of the pattern that is to be exposed can also be used.

Further, for example, the embodiment described above can also be applied to an exposure apparatus (lithography system) which forms a line-and-space pattern on a wafer by forming an interference fringe on the wafer.

Furthermore, as disclosed in, for example, U.S. Pat. No. 6,611,316, the embodiment described above can also be applied to an exposure apparatus that synthesizes two reticle patterns on a wafer via a projection optical system, and by performing scanning exposure once, performs double exposure of one shot area on the wafer almost simultaneously.

Incidentally, in the embodiment described above, the object (the object subject to exposure on which an energy beam is irradiated) on which the pattern is to be formed is not limited to a wafer, and may be another object such as a glass plate, a ceramic substrate, a film member, or a mask blank and the like.

The usage of the exposure apparatus is not limited to the exposure apparatus used for producing semiconductor devices, and for example, can also be widely applied to an exposure apparatus for liquid crystal displays used to transfer a liquid crystal display devices pattern on a square shaped glass plate, or an exposure apparatus used to manufacture an organic EL, a this film magnetic head, an imaging device (such as a CCD), a micromachine, a DNA chip and the like. Further, the embodiment described above can also be applied not only to an exposure apparatus for producing microdevices such as semiconductor devices, but also to an exposure apparatus which transfers a circuit pattern on a glass substrate or a silicon wafer, in order to manufacture a reticle or a mask used in a light exposure apparatus, an EUV exposure apparatus, an X-ray exposure apparatus, and an electron beam exposure apparatus and the like.

Electronic devices such as semiconductor devices are manufactured through the following steps; a step where the function/performance design of the device is performed, a step where a reticle based on the design step is manufactured, a step where a wafer is manufactured from silicon materials, a lithography step where the pattern of a mask (reticle) is transferred onto the wafer by the exposure apparatus (pattern formation apparatus) related to the embodiment previously described, a development step where the wafer that has been exposed is developed, an etching step where an exposed member of an area other than the area where the resist remains is removed by etching, a resist removing step where the resist that is no longer necessary when etching has been completed is removed, a device assembly step (including a dicing process, a bonding process, and a package process), an inspection step and the like. In this case, because the exposure method previously described is executed using the exposure apparatus in the embodiment described above, and a device pattern is formed on a wafer in the lithography step, a device with high integration can be manufactured with good productivity.

Incidentally, the disclosures of all publications, the Published PCT International Publications, the U.S. Patent Application Publications and the U.S. patents that are cited in the description so far related to exposure apparatuses and the like are each incorporated herein by reference.

### INDUSTRIAL APPLICABILITY

The mark detection method of the present invention is suitable for detecting a mark that is present on a movable body. Further, the exposure method and the exposure apparatus of the present invention are suitable for transferring a pattern onto an object. Further, the device manufacturing method of the present invention is suitable for manufacturing electronic devices such as a semiconductor device or a liquid crystal display device.

1. A mark detection method to detect a mark present on a movable body, the method comprising:
imaging the mark with a mark detection system provided externally to the movable body when the movable body is driven in a predetermined direction while measuring position information of the movable body with a position measurement system that has a measurement period in principle, during the drive of the movable body; and
obtaining a position of the mark, using an imaging position obtained from imaging results of the mark and a position of the movable body at the time of imaging of the mark obtained from measurement results of the position measurement system.

2. The mark detection method according to claim 1, wherein in the imaging, the movable body is driven by a moving distance which is an integral multiple of the measurement period in a measurement direction of the position measurement system, during the imaging of the mark.

3. The mark detection method according to claim 2, wherein the moving distance is about the same or less than a resolution of the mark detection system.

4. The mark detection method according to claim 2, wherein
in the imaging, the movable body is driven in the measurement direction by the moving distance.

5. The mark detection method according to claim 2, wherein
in the imaging, the movable body is driven by the moving distance in each of a plurality of measurement directions of the position measurement system.

6. The mark detection method according to claim 2, wherein
in the imaging, the movable body is driven in uniform velocity during the imaging of the mark.

7. The mark detection method according to claim 6, wherein
velocity of the movable body is determined from an imaging time of the mark and the moving distance.

8. The mark detection method according to claim 6, wherein
in the imaging, velocity of the movable body is measured during the imaging of the mark, and the imaging is executed again when constant velocity drive of the movable body is disturbed.

9. The mark detection method according to claim 1, wherein
in the imaging, a plurality of measurement results of the position measurement system is collected during the imaging of the mark, and
in the obtaining the position of the mark, an average of the plurality of measurement results serves as a position of the movable body at the time of imaging of the mark.

10. The mark detection method according to claim 9, wherein
in the imaging, a timing of imaging of the mark and a timing of collecting measurement results of the position measurement system are made to be synchronous.

11. The mark detection method according to claim 1, wherein
in the imaging, a driving direction is changed each time a plurality of marks present on the movable body is imaged.

12. The mark detection method according to claim 1, wherein
the position measurement system is a measurement system that irradiates a light beam on a measurement surface provided at one of a movable body which moves holding the object and an exterior portion of the movable body, and has at least part of a portion that receives a return beam from the measurement surface placed at the other of the movable body and the exterior portion of the movable body.

13. An exposure method to form a pattern on an object by irradiating an energy beam, the method comprising:
detecting at least one of a mark on the movable body holding the object and a mark on the object by the mark detection method according to claim 1; and
forming the pattern on the object by driving the movable body holding the object based on detection results of the mark and alignment of the object, and irradiating the energy beam on the object.

14. A device manufacturing method, comprising:
exposing an object by the exposure method according to claim 13; and
developing the object which has been exposed.

15. An exposure apparatus which forms a pattern on an object by irradiating an energy beam, the apparatus comprising:
a movable body which moves holding the object;
a position measurement system having a measurement period in principle that measures position information of the movable body;
a mark detection system provided externally to the movable body that images a mark on the object; and
a controller which obtains a position of a mark by driving the movable body in a predetermined direction while measuring position information of the movable body with the position measurement system and imaging the mark on the object held on the movable body using the mark detection system during the driving of the movable body, using an imaging position of the mark obtained from imaging results of the mark and a position of the movable body at the time of imaging of the mark which is obtained from measurement results of the position measurement system.

16. The exposure apparatus according to claim 15, wherein
the controller drives the movable body by a moving distance which is an integral multiple of the measurement period in a measurement direction of the position measurement system, during the imaging of the mark.

17. The exposure apparatus according to claim 16, wherein
the moving distance is about the same or less than a resolution of the mark detection system.

18. The exposure apparatus according to claim 16, wherein
the controller drives the movable body by the moving distance in the measurement direction of the position measurement system, on the imaging.

19. The exposure apparatus according to claim 16, wherein
the controller drives the movable body by the moving distance in each of a plurality of measurement directions of the position measurement system, on the imaging.

20. The exposure apparatus according to claim 16, wherein
the controller drives the movable body in uniform velocity during the imaging of the mark, on the imaging.

21. The exposure apparatus according to claim 20, wherein
velocity of the movable body is determined from an imaging time of the mark and the moving distance.

22. The exposure apparatus according to claim 20, wherein
the controller measures velocity of the movable body during the imaging of the mark, and the imaging is executed again when constant velocity drive of the movable body is disturbed.

23. The exposure apparatus according to claim 15, wherein
the controller collects a plurality of measurement results of the position measurement system during the imaging of the mark, and an average of the plurality of measurement results is to serve as a position of the movable body at the time of imaging of the mark.

24. The exposure apparatus according to claim 23, wherein
the controller synchronizes a timing of imaging of the mark and a timing of collecting measurement results of the position measurement system on the imaging.

25. The exposure apparatus according to claim 15, wherein
the controller changes a driving direction each time a plurality of marks present on the movable body is imaged.

26. The exposure apparatus according to claim 15, wherein
the position measurement system is a measurement system that measures position information of the movable body by irradiating a light beam on a measurement surface provided at one of the movable body and an exterior portion of the movable body and receiving a return beam from the measurement surface, and has at least part of a portion placed at the other of the movable body and the exterior portion of the movable body.

27. The exposure apparatus according to claim 26, wherein
a diffraction grating is formed on the measurement surface, and
the position measurement system includes an encoder system structured from an encoder head which measures a position of the movable body in a period direction of the diffraction grating.

28. The exposure apparatus according to claim 15, wherein
the position measurement system includes an interferometer system structured from an interferometer that measures an optical path length of the measurement beam.

29. The exposure apparatus according to claim 15, wherein
the controller forms the pattern on the object by driving a movable body holding the object based on detection results of the mark and alignment of the object, and irradiating the energy beam on the object.
